(19) United States
(12) Patent Application Publication
(10) Pub. No.: US 2026/0269577 A1
(43) Pub. Date: Sep. 10, 2026

(54) A POWER CONVERTER ASSEMBLY WITH AN ELECTRICAL CONDUCTOR MANUFACTURED BY ADDITIVE MANUFACTURING

(71) Applicant: KK Wind Solutions A/S, Ikast (DK)

(72) Inventors: Bjorn Rannestad, Aalbong (DK); Jorgen Dahl Vestergaard, Kibaek (DK); Poul Thing, Ikast (DK)

(21) Appl. No.: 19/167,328

(22) PCT Filed: Mar. 22, 2024
(86) PCT No.: PCT/DK2024/050071

§ 371 Date: Sep. 19, 2025

(30) Foreign Application Priority Data
Mar. 28, 2023 (DK) PA202370156
Apr. 27, 2023 (DK) PA202370206
May 26, 2023 (DK) PA202370264

(51) Int. Cl. H02B 1/20; B33Y 80/00; H02B 1/56; H02G 5/10; H02M 3/00; H02M 7/00; H05K 7/20

(52) U.S. Cl. CPC H02B 1/20; B33Y 80/00; H02B 1/565; H02G 5/10; H02M 3/003; H02M 7/003; H05K 7/20909; H05K 7/20927; H05K 7/20936; H05K 7/20945

(57) ABSTRACT

An electrical cabinet including a high-power converter. The high-power converter includes at least three power modules, at least one reactor, and a cooling system configured for cooling the at least three power modules and the at least one reactor. A plurality of high-power electrical conductors establish a three-phased current path from a power inlet of the electrical cabinet via the at least three power modules and the at least one reactor to a power outlet of the electrical cabinet. At least one of the high-power electrical conductors is manufactured at least partly by an additive manufacturing process.

### FIELD OF THE INVENTION

The invention relates to high-power converter, use of a high-power converter and a high-power converter assembly comprising a electrical conductor manufactured by additive manufacturing.

### BACKGROUND OF THE INVENTION

In the art various of types of power converters are known including Modular Multilevel converter and a so-called back-to-back power converter. The building blocks of these known power converter types include switching modules which may include capacitors, which may be referred to as an inverter or a rectifier, cooling, reactors, capacitors, etc.

Power converters are typically enclosed in one or more electric cabinet depending on sizes. In these electric cabinets, the building blocks are electrically connected with busbars or cables. It is known to cool the switching modules (also referred to as power modules) be circulating a cooling liquid to a plate to which the power modules are mounted. It is also known to cool reactors by circulating a cooling liquid. Further, it is known to establish a flow of cooling fluid, typically air, from an air inlet to an air outlet, such flow may be established by a fan.

A limiting factor in high-power converter design when reaching current levels of 500 A, 1000 A or even higher is thermic i.e. e.g. power modules need to be cooled to keep the temperature inside the electric cabinet below a temperature threshold. Therefore, e.g. cooling systems are large in size to comply with the temperature requirements. This is one of several problems solved by the present invention as will be described below.

### SUMMARY

The inventors have identified the above-mentioned problems and challenges related to temperature requirements and solved these problems by the present invention as described below.

In an aspect, the invention relates to a three-phased high-power converter comprised by an electrical cabinet, said high-power converter comprising:
at least three power modules,
at least one reactor,
a cooling system configured for cooling said at least three power modules and said at least one reactor, and
a plurality of high-power electrical conductors establishing a three-phased current path from a power inlet of said electrical cabinet via said at least three power modules and via said at least one reactor to a power outlet of said electrical cabinet,
   wherein at least one of said high-power electrical conductors are manufactured at least partly by an additive manufacturing process.

Manufacturing a high-power electrical conductor (referred to simply as conductor or electrical conductor) by an additive manufacturing process is advantageous in that additive manufacturing is suitable for manufacturing complex shapes and is thus advantageous to employ for manufacturing of electrical conductors where these are used in narrow spaces such as in an electrical cabinet. Particularly, geometrical features of the electrical conductor, such as individual conductor branches, outgrowths, recesses, internal structures, etc. may be directly manufactured additively. Thus, using additive manufacturing for manufacturing an electrical conductor of a high-power converter is advantageous since it may permit tailoring the geometry of the electrical conductor to the conditions/design of the high-power converter and/or the electrical cabinet comprising the high-power converter.

Hence, a converter according to the present invention comprising an electrical conductor manufactured by an additive manufacturing process is advantageous in that weight and cost of materials are reduce due to less material being used for the electrical conductors. Further, cooling of the converter is improved in that surface area of the electrical conductor can be increased and the electrical conductor can be manufactured with internal channels.

Further, assembling of the converter may be faster due to a reduced number of connections of electrical conductors and to more flexible electrical conductors compared known busbars. These effects may all contributed to a more compact design of the high-power converter.

Further, the electrical conductors may be designed to reduce airflow from an air inlet to an air outlet of an electric cabinet as little as possible. In fact, it may be possible to design the electrical conductors with a geometry that is guiding air flow in a predetermined direction. A predetermined direction may be towards a heat sink, a connection between conductor and component, an opening to an internal channel of the conductor, etc.

An electrical conductor may be implemented as a cable or a busbar. Busbars are in the art known as massive Cobber or Aluminium bars which are typically used to distribute current between electrical components inside the electrical cabinet. A conductor according to the present invention may be manufactured by an electric conductive material.

In an exemplary embodiment of the invention, said three-phased high-power converter further comprises support structure configured to secure said high-power electrical conductors to a frame of said electric cabinet.

Especially the part of the high-power electrical conductors that are implemented as cables are important to fix e.g. every 30 cm or less to ensure sufficient support in case of an explosion caused e.g. by a short.

Especially, the support for the part of the high-power electrical conductors that are implemented as busbars need to be isolated in that typically the individual busbars are not isolated.

In an exemplary embodiment of the invention, at least part of said support structure is at least partly manufactured by an additive manufacturing process.

Manufacturing the support structure by an additive manufacturing process is advantageous in that it may be designed with the dual purpose of supporting e.g. a busbar and guide a cooling air flow through the electric cabinet. At least it may be designed and manufactured so as not to block or reduce the flow of cooling air through the electrical cabinet.

In an exemplary embodiment of the invention, said three-phased high-power converter further, comprises at least one component from the list comprising: circuit breaker, fuse, current sensors.

Components of the mentioned list may be connected to each other or to a busbar for conducting current to or from the component. The connection may advantageously be made by a conductor manufactured by an additive manufacturing process.

In addition it should be motioned that components for securing or assisting in securing components and conductors may also be manufactured by an additive manufacturing process. In fact such fastening clamps may be designed as flexible clamps assisting in damping vibrations of the components/conductors.

In an exemplary embodiment of the invention, at least part of a core or at least one winding of at least one of said at least one reactor are at least partly manufactured by additive manufacturing.

Manufacturing by additive manufacturing enables complex designs of core and particularly windings. Thus, a reactor optimized with respect to thermal conductivity and material consumption can be manufactured.

In an exemplary embodiment of the invention, said at least part of said core and said at least one winding comprises an internal channel.

By using additive manufacturing to manufacture a core or winding of a reactor it is possible to manufacture the core or winding with an internal channel. This is advantageous in that the cooling (or heating) of the reactor can be optimized by connecting such channel to a cooling loop of the cooling system.

In an exemplary embodiment of the invention, said cooling system comprises a heat exchanger and a first cooling loop configured to circulate a liquid cooling fluid from said heat exchanger via a first part of said first cooling loop to a power module mounting plate and via a second part of said first cooling loop back to said heat exchanger.

In an exemplary embodiment of the invention, said cooling system further comprises a second cooling loop configured to circulate a liquid cooling fluid from said heat exchanger via a first part of said second cooling loop to an internal cooling channel of at least one of said at least one reactor and via a second part of said second cooling loop back to said heat exchanger.

In an exemplary embodiment of the invention, said heat exchanger is located external to said electrical cabinet.

This is advantageous in that it has the effect, that the most heat generating components of the power converter i.e. the power modules and the reactors are liquid cooled. Thus, heat generated from these components are transported with the liquid cooling fluid to the heat exchanger and thereby out of the electrical cabinet.

In an exemplary embodiment of the invention, said cooling system further comprises a fan configured for establishing an air flow from an air inlet towards an air outlet.

This is advantageous in that it has the effect that components not cooled by the liquid-based cooling system is also cooled.

In an exemplary embodiment of the invention, at least part of said high-power electrical conductors are selected from the list comprising: main busbar, transition busbar and current balancing busbar.

A main busbar should be understood as an electrical conductor distributing current in an electrical cabinet, a switchgear, panel board or busway enclosure, typically, from one or more cables entering the electrical cabinet to electrical components located inside the electrical cabinet. Typically, the main busbar extends in the width (X direction) or in the height (Y direction) of the electrical cabinet. The main busbar may be fastened to the back plate of the electrical cabinet.

A transition busbar should be understood as a busbar connecting a main busbar or cable with another main busbar, another transition busbar, with an electrical component, or the like. A transition busbar may also be referred to as a connection or transition piece for connecting two or more electrical components. Typically, a transition busbar extends in two or more directions, where one of these directions is towards the opening of the electrical cabinet (Z direction). Another of these directions is typically perpendicular or parallel to e.g. the main busbar to which transition busbar is connected. The transition busbar may comprise two legs at one end for connecting e.g. two paralleled power modules to one main busbar or to another transition busbar.

A current balancing busbar should be understood as a variant of a transition busbar. A current balancing busbar may e.g. be a transition busbar having two or more legs or sets of terminals allowing the connection of two or more power modules i.e. allowing parallelling the power modules. This is advantageous in that it has the effect, that if such current balancing busbar is connected to e.g. two power modules, then the current into or out of these two power modules can be balanced. Such balancing is done via designing the current balancing busbar so that the current path through the two legs of the current balancing busbar has the same ohmic resistance. When this is achieved an equal share of current to and from the power modules is conducted via the two legs. Thereby it is achieved that losses are the same in both legs leading to equal wear and temperature increase.

In an exemplary embodiment of the invention, said at least one reactor comprising an electrical winding comprising an inner part and an outer part, wherein a diameter of said inner part is smaller than the diameter of said outer part.

In this context inner part should be understood as the part of the electrical winding which is surrounded by a core. In case a plurality of electrical windings exists the inner part of such plurality of windings are the parts that are facing each other.

In this context outer part should be understood as the part of the electrical winding which is opposite of the inner part i.e. not surrounded by a core.

It is advantageous to have an outer part with a diameter that is bigger than the diameter of the inner part. A bigger diameter leading to a better heat dissipation. Further, heat generated in the inner part can propagate to the outer part of the electrical winding and thereby facilitating heat to easily dissipate from the inner part to the surroundings.

In this context diameter should be understood as the physical measurable diameter. Hence, there is no need to cut or calculated the diameter, it can simply be measured directly with a caliper.

In an exemplary embodiment of the invention, said outer part of said electrical winding comprises a geometry which is comprised by the list comprising: bionic, web, sponge, twisted and honeycomb.

Such geometry of the outer part is advantageous in that when one of the above-mentioned geometries are chosen, the amount of material used for the electrical winding is reduced. It is also an advantage that the surface of such geometries of the electrical winding is increased in that more surface is then available for cooling.

For all the bionic, web, sponge, honeycomb and twisted like geometries these structures, are good for cooling down the electrical winding. The geometries all comprise less material with a big surface, so the smaller amount of material is easier to cool down and provides a more compact geometry/electrical winding.

In an exemplary embodiment of the invention, at least one current path branches off through said electrical winding.

This is advantageous in that it has the effect that not all current need to be conducted along one path through the electrical winding. Thereby spacing of electrical conductors are facilitated leading to an optimized cooling of the electrical winding. Thus, the geometry is formed by one or more conductor branches.

Further, allowing a current path to branch one or more times along the longitudinal direction of the electrical winding is advantageous in that it has the effect, that the geometry of the electrical winding can be changed compared to traditional massive electrical windings. A change in geometry allows the electrical winding to take advantage of the fact, that the space outside the core is much larger than the space inside the core.

Further, the electrical winding can be made self-supported or part of a support structure for other components, the surface areas is increased leading to better cooling and optimized according to skin-effect at high frequencies, etc.

In an exemplary embodiment of the invention, said high-power electrical conductor is manufactured at least partly with a concave geometry in the surface of a middle segment or one of a first end and a second end of said high-power electrical conductor.

This is advantageous in that such concave geometry may form a funnel like geometry guiding a flow of air caught by said funnel to an inlet opening of an internal channel of said electrical conductor or through the electrical conductor if the design thereof allows so. It should be mentioned that air guides provided in the surface of said electrical conductor may assist in guiding a flow of air into said funnel.

It should be noted that the air guides described in this document may also be applied to or made in the surface of the ends of the electrical conductor.

In an exemplary embodiment of the invention, at least one of said first end and said second end are monolithically formed with said middle segment.

In an exemplary embodiment of the invention, wherein at least one of said plurality of high-power electrical conductors are manufactured in an airy geometry.

Airy design should be understood as a design comprising one or more conductor branches designed in such a way that air or other cooling fluid may pass through the conductor branches and thereby facilitate cooling the conductor branches. Examples of such an airy design include weblike, spongy, bionic, twisted, etc.

In an exemplary embodiment of the invention, said high-power electrical conductor has a resonance vibration frequency of at least 5 Hz, for example at least 20 Hz, for example at least 30 Hz, for example at least 70 Hz, for example at least 150 Hz for example at least 300 Hz, for example at least 500 Hz.

The electrical conductor is advantageously designed and subsequent manufactured so that it has a resonance vibration frequency associated with relative motion between the first end segment and the second end segment that is does not coincide with a natural frequency of the system in which it is included. This is to avoid vibrations initiated by natural frequencies from such electric system or mechanical system. An example of a mechanical system is a wind turbine which may have a natural frequency of 5 Hz.

In an exemplary embodiment of the invention, at least a middle segment of at least one of said plurality of high-power electrical conductors comprises at least one internal channel.

The internal channel may be a closed channel for guiding a liquid or gaseous coolant through the interior of the busbar. Alternatively, it may be an open channel for guiding an air flow through the interior of the busbar. It should be mentioned that guiding an air flow through the interior of the busbar should be understood as guiding air behind the outer surface of the busbar i.e., along the side or behind a conductor branch of the busbar. Accordingly, it is understood that the conductor, in particular part of the middle segment of the conductor is manufactured with a plurality of conductor branches forming air gaps through which air can flow.

Further the internal channel may be used for heating the conductor which may be relevant prior to start-up of the converter.

In an exemplary embodiment of the invention, said at least one internal channel is included in a third cooling loop and configured to guide a cooling fluid circulated in said third cooling loop through the interior of said at least one of said plurality of high-power electrical conductor.

An internal channel used for cooling and configured to guide a cooling fluid through at least part of the high-power electrical conductor is advantageous in that in this way, the temperature of the high-power electrical conductor, especially around the internal channel, can be controlled such as reduced. Hence, an internal channel is advantageous in that it has the effect, that an efficient temperature regulation of the electrical conductor is possible.

Further, internal channels used as cooling channels are advantageous in that heat is transported out of the electrical cabinet more efficiently than by using a fan to establish a flow of air out of the electrical cabinet. Since, at the high amps a power converter of the present invention is operating at, heat is a very important design factor. Thus, the better the temperature can be controlled, more efficient it is possible to operate the power converter. Therefore, it is important to be able to remove as much heat as possible from the inside of the electrical cabinet.

Accordingly, electrical conductors having both an internal channel for conducting liquid or gaseous cooling fluid and a bionic-like geometry is advantageous to use for conducting current inside an electrical cabinet comprising a power converter operating with currents above 100 A.

In this document is mentioned a first, second and third cooling loop. It should be noted that these cooling loops may be combined in any desired way to optimize the cooling of the high-power converter.

In an exemplary embodiment of the invention, at least one of said plurality of high-power electrical conductor comprises at least two, preferably at least three, most preferably at least four internal channels.

Having more than one internal channel is advantageous in that it has the effect, that the electrical conductor then has more surface when high frequency current is conducted due to the skin effect. Further, this is advantageous in that it has the effect, that a larger part of the cross-sectional area of the electrical conductor is possible to temperature regulate. Further, this is advantageous in that it has the effect, that fluids having different temperatures can flow through the electrical conductor. A plurality of channels also allows to circulate the same fluid forth and back between the ends of the middle segment/first and second ends. Alternative, it allows to have several separate flows.

In an exemplary embodiment of the invention, said at least one internal channel is configured to comprise a cooling pipe.

A cooling pipe/polymer tube e.g. in the form of an insulated hose may be inserted into the internal channel e.g. when the electrical conductor with internal channel is manufactured. This is advantageous in that it has the effect, that no connection of external channel and internal channel is needed. The cooling pipe may simple be circulating the cooling fluid from a heat exchanger to through the electrical conductor via the internal channel and back to the heat exchanger in one and the same pipe. The same pipe may, depending on temperatures, be used to heat the conductor in which is provided.

In an exemplary embodiment of the invention, said at least one internal channel comprises a plurality of flow guides.

Flow guides are advantageous in that they have the effect that they may be designed to establish a particular flow of fluid inside the internal channel. Such particular flow may include establishing a swirling effect in the flow of e.g. a flow of cooling fluid inside the internal channel and thereby increase cooling effect of the fluid.

In an exemplary embodiment of the invention, said at least one internal channel is monolithically formed with at least part of an external channel.

Monolithically formed the internal channel and at least part of an external (to the electrical conductor) channel is advantage in that mounting of the internal channel to a cooling system is easy. In fact, an additional part of the external channel such as a plastic pipe may be connected to the part of the external channel monolithically formed with the inner channel with a hose clamp.

In an exemplary embodiment of the invention, at least one of said plurality of high-power electrical conductors comprises at least one air guide.

An electrical conductor comprising an air guide is advantageous in that it has the effect, that it facilitates both guiding a cooling fluid, such as air, to and possible also around an electrical component to which it is connected or passing by in an electrical cabinet. Such catching and guiding of air flow is achieved while, at the same time, improving the cooling of the electrical conductor itself and supplying the electrical component with power without the need for additional air guiding components.

In an exemplary embodiment of the invention, said at least one air guide is removably attached to said at least one high-power electrical conductor.

This is advantageous in that it has the effect, that it is possible to adjust the position of the air guide on the electrical conductor. Thus, it is possible to adjust airflow directly to a hot spot e.g. of an electrical component or an area which need cooling by airflow.

In fact, it may be possible during operation of an electrical system to establish a thermography of the electrical system and based on an evaluation of the resulting picture adjust or position one or more the air guides to guide flow of air to relevant areas

In an exemplary embodiment of the invention, said at least one air guide is an integrated part of said at least one high-power electrical conductor.

An integrated air guide is advantageous in that it has the effect, that no additional components is needed to distribute an air flow around or along the electrical conductor.

In an exemplary embodiment of the invention, at least one of said plurality of high-power electrical conductors comprises at least one integrated heat sink.

An electrical conductor such as a middle segment hereof comprising an integrated heat sink is advantageous in that not only does such electrical conductor facilitate improved cooling of the electrical conductor itself, e.g. when used as a high-power busbar for conducting currents to or from a component to which it is connected. But such middle segment advantageously also enabling cooling of a component such as a power electronic component such as a power module by mounting the power modules with a thermal connection to the electrical conductor with an integrated heat sink. Thereby eliminating or reducing the need of separate heat sinks for components such as power modules.

The heat sink may provide a larger surface area of the electrical conductor where it is located compared to other parts of the electrical conductor where no heat sink is located.

In addition, or alternatively a heat sink may provide a more open surface of the electrical conductor, particularly of the middle segment, compared to parts of the electrical conductor which have no heat sink.

In an exemplary embodiment of the invention, said at least one heat sink is removably attached to at least one of said plurality of high-power electrical conductors.

This is advantageous in that it has the effect, that it is possible to adjust the position of the heat sink on the electrical conductor. Thus, it is possible to adjust heat sink capacity directly to a hot spot e.g. of an electrical component or an area which need cooling by airflow.

In fact, it may be possible during operation of an electrical system to establish a thermography of the electrical system and based on an evaluation of the resulting picture adjust or position one or more heat sinks to increase cooling at relevant areas.

In an exemplary embodiment of the invention, said at least one heat sink is an integrated part of said at least one of said plurality of high-power electrical conductors.

In an aspect, the invention relates to the use of a high-power converter according to any of the preceding claims in a renewable energy generating facility.

A renewable energy generating facility should be understood a wind turbine, windfarm, solar panel, solarfarm, etc including substations needed to connect the renewable energy generating facility to the utility grid.

In an aspect, the invention relates to a high-power converter assembly comprised by an electrical cabinet, said power converter assembly comprising: a power conduction section comprising high-power electrical conductors, a power conversion section comprising a plurality of power modules, a filtering section comprising a plurality at least one reactor, an auxiliary section, comprising auxiliary components and a cooling system (4), wherein components of said power conversion section (SB), said filtering section (SC) and said auxiliary section (SD) is connected via high-power electrical conductors (1), wherein said cooling system (14) is configure for local cooling of at least said power conversion section (SB) and said filtering section (SC), characterised in that at least one of said high-power electrical conductors (1) is at least partly manufactured by an additive manufacturing process.

A high-power converter comprising components that are connected by conductors that are manufactured by additive manufacturing may have an airy design or geometry leading to an optimized cooling.

Further such high-power conductor may be manufactured with an integrated heat sink, with air guides, etc. which may optimized cooling of the conductor and reduce the amount of material needed to manufacture the conductor. This leads to a reduction of weight of the high-power converter which has many spillover effects e.g. in terms of logistics and support of the cabinet assembly.

In an exemplary embodiment of the invention, said high-power converter assembly is an AC to DC, DC to AC, DC to DC or AC to AC converter.

In an exemplary embodiment of the invention, at least one of said high-power electrical conductors are manufactured with an internal channel (19)

This is advantageous in that it has the effect that the high-power electrical conductor can be cooled from the inside by a flow of cooling liquid which is advantageous over a cooling air from in that the cooling is more focused and heat can be removed from the electric panel via the cooling liquid.

In an exemplary embodiment of the invention, said at least one of said high-power electrical conductors is included in a closed liquid cooling loop of said cooling system.

This is advantageous in that it has the effect, that heat is transported directly from the inside of the conductor and out of the electric cabinet. In this way the temperature is reduced inside the electric cabinet leading to better working conditions of the power modules. Alternatively, it may lead to an increase in current possible to conductor to the power modules and/or handled by the power modules in that temperature is no longer as limiting a factor compered to power modules of known electric cabinet only cooled by an air flow on the outside of the electrical conductor.

In an exemplary embodiment of the invention, said at least one of said high-power electrical conductors is cooled by a fan.

This is advantageous if the high-power electrical conductor is manufactured in an airy design where cooling air can pass through two or more conductor branches of the high-power electrical conductor.

In an exemplary embodiment of the invention, said at least one of said high-power electrical conductors comprise airgaps between two or more conductor branches.

Preferably it is a middle section that comprises plurality of conductor branches. The individual conductor branches are spaced apart by air gaps both in the longitudinal and transversal direction of the electrical conductor. This is forming a twisted design which adds flexibility to the conductor and thus the ability to absorb vibrations. Further, the design is lightweight and easy to mount.

### THE DRAWINGS

For a more complete understanding of this disclosure, reference is now made to the following brief description, taken in connection with the accompanying drawings and detailed description, wherein like reference numerals represent like parts. The drawings illustrate embodiment of the invention and elements of different drawings can be combined within the scope of the invention:

FIG. 1A-1C illustrates various designs of an electrical conductor,

FIG. 2 illustrates a method of manufacturing an electrical conductor,

FIG. 3A illustrates a high-power converter,

FIG. 3B illustrates a power module assembly,

FIG. 4 illustrates a conductor with internal channel for cooling and heating,

FIG. 5 illustrates a power converter assembly, and

FIG. 6 illustrates an inductor with a non-uniform winding.

### DETAILED DESCRIPTION

The present invention is described in view of exemplary embodiments only intended to illustrate the principles and implementation of the present invention. The skilled person will be able to provide several embodiments within the scope of the claims.

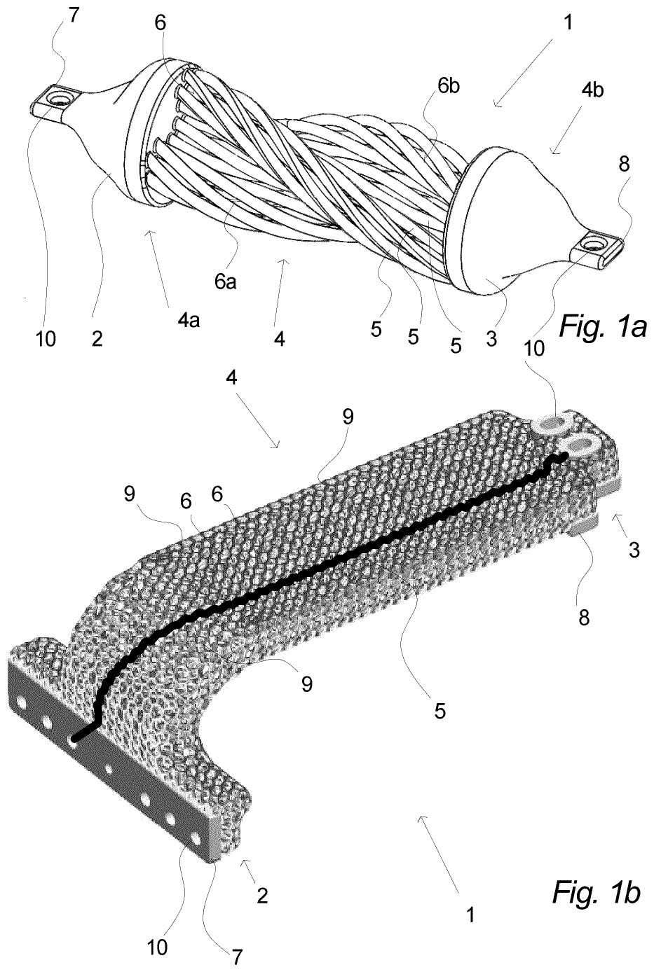

FIG. 1a-1c illustrates various embodiments of an electrical conductor 1 for use in a converter 11 according to the present invention. FIG. 1a illustrates an electrical conductor 1 having a twisted geometry/design. The electrical conductor 1 comprises a first end 2 and a second end 3, where the second end 3 being distal to the first end 2 and spaced apart from each other by a middle segment 4.

The middle section 4 in this particular embodiment comprises a plurality of conductor branches 5. In this particular embodiment the individual conductor branches are spaced apart by air gaps 6 both in the longitudinal and 6a transversal direction 6b of the electrical conductor 1. This twisted design of the conductor branches adds flexibility to the conductor 1 and thus the ability to absorb vibrations. Further, the design is lightweight and easy to mount.

In this particular embodiment, the first end 2 comprises a first terminal 7 and the second end 3 comprises a second terminal 8. The first and second terminals 7, 8 may comprise one or more terminal holes 10 for connecting the electrical conductor 1 to other electrical components. The electrical conductor 1 is configured to support conductance of an electric current between the first and second terminals 7, 8.

Each of these two terminals 7, 8 may, via terminal holes 10, clamps, plugs or other electrical connection means, for example be galvanically coupled to terminals, busbars, components (such as breakers, contactors, power modules, reactors, etc.) and other electrical conductors according to the present invention, etc. of an electrical installation such as a high-power converter. Typically, the electrical conductor 1 and thus the terminals, busbars, components, etc. to which it may be connected would be comprised by an electric box i.e. located inside an enclosure such as a panel, cabinet, etc.

In various embodiments, the electrical conductor 1 may have several first ends 2, several second ends 3, several first terminals 7, and/or several second terminals 8.

FIG. 1b illustrates an electrical conductor 1 having a web-like or lattice-like geometry/design. As the electrical conductor 1 illustrated in FIG. 1a, the electrical conductor illustrated in FIG. 1b comprises a first end 2 and a second end 3 separated by a middle section 4. The first end 2 may comprise a first terminal 7 and the second end 3 may comprise a second terminal 8. The first and second terminals 7, 8 may comprise one or more terminal holes 10 for connecting the electrical conductor 1 to other electrical components.

Between the two terminals 7, 8 conductor branches 5 in a web-like structure extend (only one is highlighted). These conductor branches meet and branch off in a plurality of intersection points 9. Note that the first and second ends 2, 3 are also partly manufactured as a web-like design as the middle segment 4. Also note, that the first and second terminals 7, 8 comprise more than one terminal hole 10. The terminal holes 10 of the terminals 7, 8 is made in a part of the ends 2, 3 which has non-perforated surface i.e. a surface different from the web-like surface of e.g. the middle segment 4 of the electrical conductor in this particular embodiment. The planar contact surface of the terminals 7, 8 around the terminal holes 10 is preferred to provide a connection surface to another flat surface with as little resistance as possible and sufficiently strong contact surface between bolt/nut and electrical conductor 1.

FIG. 1c illustrate an electrical conductor having a bionic geometry/design. As the electrical conductor 1 illustrated in FIG. 1a and 1b, the electrical conductor illustrated in FIG. 1c comprises a first end 2 and a second end 3 separated by a middle section 4. The first end 2 may comprise a first terminal 7 and the second end 3 may comprise a second terminal 8. The first and second terminals 7, 8 may comprise one or more terminal holes 10 for connecting the electrical conductor 1 to other electrical components.

The middle segment 4 in this embodiment is of a so-called bionic design, preferably achieved as a computer generated design. Such computer-generated design is provided based on input to a computer program controlling an additive manufacturing machine/process or able to export data to a controller of an additive manufacturing machine/process such as from a user or another computer. Input may include dimension, maximum current to be conducted, required strength, maximum deflection (elastic or plastic), etc. As the electrical conductor illustrated in FIG. 1b, the electrical conductor of this particular embodiment comprises both longitudinal conductor branches 5a and transversal conductor branches 5b. It is noted, that together the conductor branches 5a, 5b forms a transversal conductor branch outgrowth i.e. if seen in a side view, the electrical conductor 1 of FIG. 1c would be thicker at the middle section 4 than at the ends 2, 3. The conductor branches 5 are spaced apart in space by air gaps 6 in both X (6a), Y (6b) and Z (6c) directions. Further note, that the terminals 7, 8 are designed with a planar surface to obtain best possible contact with a component having a planar surface, to which the electrical conductor 1 is to be connected to, such as clamped against, via for example bolt and nuts. Also note, that independent from the geometry of the ends 2, 3, the terminals 7, 8 are aligned/raised so that the contact surface for, e.g., all three terminals 7 are in the same plane.

The above embodiments of an electrical conductor 1 all feature airy geometries having air gaps 6 between conductor branches 5. The electrical conductor 1 may in other embodiments feature other airy geometries such as web-like, gyroid-like, lattice-like, etc., as described in more detail herein, which in various embodiments may provide improved cooling, reduced material consumption, improved flexibility, and/or other advantages described in more detail herein. The term ‘-like’ is used in connection with gyroid-like, lattice-like, etc., to emphasize that it is an airy geometry resembling the named structure, rather than a specific systematic structure, that is relevant in preferred embodiments of the invention.

It should be noted that the three different designs of electrical conductors illustrated in FIG. 1a-1c is not limiting for the designs or geometries or structures that is possible to manufacture according to the present invention. Other designs that are possible to represent digitally and transfer to an additive manufacturing device and thus manufacture by additive manufacturing is considered to fall with the scope of the present invention. This includes designs having plane surfaces with internal ducts, manufactured by different materials, manufactures with protrusions or recesses, manufactured to have auxiliary functions beside conducting current, etc. Particularly, high-power conductors are advantageous to manufacture according to the present invention.

Note that embodiment of the invention, such as the above-described electrical conductors, may comprise further terminals 7, 8 between the ends 2, 3, which are not illustrated. Also note, that a plurality of the illustrated electrical conductors 1 may be connected to form a complete electrical conductor. In this case the first and second end 2, 3, is referred to as the ends of the complete electrical conductor which may comprise terminals 7,8 and e.g. terminal holes 10 for connecting the complete electrical conductor to other components. Between these first and second ends 2, 3 of the complete electrical conductor, terminals 7, 8 of a plurality of electrical conductors as illustrated may be connected.

The cross-sectional area of the conductor/conductor branches can be exploited to its full potential in an electrical conductor of the present invention. The conductor is designed and manufacture to have a cross-sectional area that is able to comply with requirements to current to be conducted without have excess of material used. The design of the present conductor may not have surplus material which is not used for conducting current when nominal current is supplied e.g. to a 1400 A power module. If extra material is used, this is used for cooling the conductor or a safety margin. The amount of such extra material can be determined relatively precise by the software which is used to design the conductor. As a rule of thumb, the larger surface for cooling, the higher amps is possible to conduct. The design software may be able to put weight on amps, cooling properties (cooling medium, surface, etc.), frequency of the current when designing the geometry of the conductor, etc. when designing the conductor. Accordingly, a conducting cross-sectional area of a conductor as illustrate in FIG. 1b may be 80 mm2 may in certain embodiments be sufficient to conduct a current of 1300 A due to the airy design allowing a very advantageous cooling. In fact, tests have shown that the temperature of a conventional massive busbar with a conducting cross-sectional area of 516mm2 conducting 1300 A increases to a temperature where neighboring components of plastic is in risk of melting.

Hence, it should be noted that the conductor may be designed and subsequently manufactured so that a percentage of the cross-sectional area of the electrical conductor e.g., above 80% such as between 90% and 100% is used to conduct current during normal operation. This is in contrary to known massive busbars that does not exploit the material in its center to conductor current. This is at least true for most frequencies of currents conducted in high-power systems including renewable systems, vehicles and the like.

The high percentage of utilization of cross-sectional area for conducting current compared to known massive conductors is possible to obtain in that the conductor of the present invention and thus the individual conductor branches because they are designed with a cross-sectional area that sums up to be able to conduct a current of a given frequency. Further, the material reduction is also made possible because of the possibility of cooling also inside the conductor. In fact, a conductor branch may along most of its length, in some embodiments along all of its length, be cooled from all angles i.e. a 360° cooling of the conductor branches is possible.

As mentioned, a conductor of the present invention may form an airy geometry which depending on the kind of airiness may not facilitate a secure or robust platform or structure for fastening the conductor e.g. to the electric cabinet. Accordingly, in proximity of through-holes for fastening the conductor or through-holes, e.g. terminal holes, for connecting the conductor to components or other conductors, the geometry of the conductor may not be airy. Preferably, around a through-hole the density of the conductor is higher or more concentrated to form an, e.g., planar surface and thereby provide the best possible preconditions for conducting current between two parts of a joint and to distribute the force required to fastening a conductor in the joint or to a support structure. Hence, a through-hole may be designed as a cylinder through which a bolt may pass through and with planar upper and lower parts extending from the periphery of the cylinder to facilitate the force and/or current distribution in the joint. Other mounting and/or terminal points may be preferred in some embodiments, such as flanges, protrusions, plugs or sockets, etc., with or without through-holes, but with the same consideration of ensuring sufficient robustness and stability of the electrical conductor for the intended mounting or connection method. The through-holes could be 6 mm, 8 mm, 10 mm or 12 mm in diameter.

It should be mentioned that terminals for electrical connection may be positioned at or between the ends of an electrical conductor. Thus, in principle, a conductor may be manufactured by an additive manufacturing process and when the first end and first part of the middle segment is manufactured these may be rolled onto a conductor holder as the middle segment is continued to be manufactured. Alternative, the conductor is guided out of the printing areas e.g. by a conveyer belt as the conductor is manufactured. This may result in a long conductor with two ends. Either during manufacturing or after, terminals may be made in the conductor and also after manufacturing, the conductor may be cut into desired lengths. In this way, terminals may be manufactured or provided either at the ends or between the ends of the conductor.

The term monolithic is in this description used to describe the geometry or structure of an electrical conductor according to the present invention. Such conductor is preferably manufactured by an additive manufacturing process and thereby, it is manufactured as a single piece, unit or block from one end to the other or at least one end and a middle segment is manufacture as a single piece. Such conductor may thus be formed from a single material as a single piece, unit or block where its one or more ends are monolithically formed with a middle segment connecting the one or more ends i.e. monolithically formed should be understood as made in one continuous process with no need for additionally adding one part to another I.e. one or more ends are manufactured together with the middle segment as one unit with no connections such as welding, soldering, or by any clamping or fastening means, except for the type of micro binding intrinsic to the particular additive manufacturing technology utilized, such as, e.g., layer-by-layer melting, sintering, liquid binding, spraying, etc. With this said, it should be mentioned, that it is possible to add additional elements such as terminals, cooling fins, etc in a post manufacturing process e.g., by a cold spray process.

Put in another way a conductor of the present invention is the result of a process forming the conductor in one structure, a conductor composed of an electrically conductive material without joints or seams and thus constituting a conductor as a rigid whole exhibiting a rigidly fixed uniformity. To such conductor it is possible to connect additional conductors via terminals and thereby branch off one current path to two or more current paths or vice versa.

It should be mentioned that the conductor may be manufactured from more than one type of material. In this situation, the conductor could be said to be polylithic. The term polylithic should in this context be understood as a geometry or structure of an electrical conductor that is manufactured in one piece as a monolithic structure, as described above, where the conductor is manufactured from two or more materials. Hence, a polylithic conductor of the present invention is a conductor resulting from a process forming the conductor in one structure where the process is using two or more different materials. Such two or more materials may be a combination of electrical conductive or non-conductive materials.

In most embodiments, the electrical conductor 1 is designed to comply with high voltages i.e. voltages above 24V such as 110V, 230V, 400V, 690V, 1000V, 1500V and up to kV systems. just to mention a few voltage levels of an electrical installation in which the electrical conductor 1 of the present invention would be suitable. In terms of current, an electrical conductor 1 according to the present invention may be designed to conduct several hundreds of amps (16, 32, 64, and so on up to 100, 200 and so on up to e.g. 900 A) up to a couple of thousand amps (1000 A-3000 A). Electrical conductors may be designed to conduct higher currents than 3000 A e.g. by improving cooling of the conductor in combination with an increased cross-sectional area of the conducting part of the conductor.

Mentioning these voltages, it should be noted, that in principle there are no lower limits as to the voltage and current. I.e., versions of the electrical conductor may be designed to be used in, e.g., 3.3V, 5V, 9V, 12V, 15V, 20V, 24V or 48V systems, such as USB power delivery PD systems, conducting currents below, e.g., 10 A, such as 5 A, 3 A, 2.4 A, or 2 A just to mention a few examples.

Thus, the electrical conductor 1 of the present invention is suitable for use in almost any type of electrical installation. This includes everything from low voltage to high voltage AC and or DC systems where transfer/conducting of current or communication signals is needed.

The present invention is particularly advantageous for electrical busbars designed for high-power electrical systems, e.g. from 10 kW and up, such as 22 kW, 50 kW, 110 kW, 150 kW, 225 kW, 300 kW, 350 kW, 500 kW,800 kW,1MW, 2MW, 3MW, or even higher, such as e.g. 5MW or 10MW systems, with voltages of e.g. 110V, 230V, 400V, 690V, 800V, 1000V, 1500V, 6 kV or e.g. 10 kV, and currents from e.g. 16A, 32A or 64A, to several hundreds, e.g. 100 A, 200 A or 500 A, or even thousands, e.g. 1000 A to 4000 A. By local connecting busbar is referred to busbars for local connections inside such a high-power electrical system, e.g. contained inside an electrical cabinet housing a power converter, inverter, transformer, generator, electric motor, breaker, high-power battery system, battery charger, or similar power systems, possibly including capacitors, reactors or inductors, power resistors, dump loads, etc. A system, component or conductor may be categorized as a high-power system, component or conductor if it is operating at currents in the range of 800-1000 A or higher.

Non-limiting examples of such electrical installations/systems include energy facilities such as grid components such as substations with grid support, voltage regulation, power to x plants, etc., energy generating systems such as wind turbines, wind farms, solar plants, etc., electric installations in a private homes and industry, industrial machines, household appliances, etc. and means for transportation such as airplanes, heavy duty vehicles, light duty vehicles such as automobiles, trains, ships, etc.

Accordingly, the electrical conductor may be a high-power electric conductor of a high-power electric system. In a high-power electric system, conductors may be spaced apart and/or isolated from each other with greater distances than what is possible e.g. in an electrical motor. This distance is referred to as a safety clearance and the size of it depends on the voltage differences in the system. Thus, when depending on air as isolator between an otherwise non-isolated busbar/conductor and another conductor or structure of conductive material such as a metal cabinet, the distances must be taken into account in compliance with safety regulations. It should be mentioned that air quality/pollution degree, such as humidity and particle content, may also be relevant for the distance of the safety clearance. In case a conductor is used in a high-voltage system the surface is manufactured to reduce field concentrations.

Further, the cross-sectional area of a current path through a conductor according to the present invention is larger than the cross-sectional area of e.g. a winding of an electric motor. This may be true both with respect to a cross-sectional area at a given point of the conductor and over a distance of e.g. 20 cm or 30 cm in the longitudinal direction of the conductor and physical dimensions.

Current conducting busbars of a high-power installation or system is typically fastened to a structure comprising the system for every 25-35 cm. If the current is conducted by cables, the distance between cable fasteners may be even smaller. The fastening may be made by screwing bolts into a support structure such as an electric cabinet or by screwing clamps to the support structure which is then closed and thereby fastening the cable/busbar. The conducting cables/busbars are of course insulated from the support structure.

In such high-power installations where the primary aim of conductors is to distribute electric energy to components, the magnetic field around a conductor of the present invention is not as important as it is e.g. around a winding of an electrical motor. Thus, since the magnetic field is not the main purpose for manufacturing the electrical conductor for a high-power installation the conductor is typically not designed to have a certain magnetic field when conducting current.

Further, again comparing to e.g. a winding of an electrical motor, a conductor of the present invention would as a general rule be designed with a surface area that is as large as possible to optimize the possible advantages of the invention as described herein. Depending on the purpose of the conductor, the surface may for example be designed for conducting current, conducting current and heat dissipation or heat dissipation. Thus, even though all portions of a conductor of the invention may comprise an electric conductive material, not all portions are necessarily used for conducting current through the conductor. In general, the available area around a conductor is exploited to expand the surface of the conductor for one of, for example, the heat dissipation or current conducting purposes, or other described purposes such as improved flexibility, reduced material consumption, air guidance, etc. The available area is limited by safety clearances to other conductors of different phases having different voltage levels, grounded structures such as elements of an electric cabinet, etc.

An example of a portion of a conductor that is primarily used for non-conducting purposes such as heat dissipation or air guidance, is an outgrowth from the surface of the conductor which is not connected at the distal end of where it is growing from the surface of the conductor. Such outgrowth or protrusion may for heat dissipation purposes preferably comprise some kind of bionic design with airgaps between branches, possibly with a continuous surface towards a direction of air flow for air guidance purposes. Such portions would be referred to as conductor branches if these were part of the middle segment conducting current form one end to the other. Such outgrowth may in principle take any form or geometry exploiting the free space around the area as long as safety clearance distances are maintained. In such examples, the fraction of current conducted by the surface area of the outgrowing conductor portion is very small if not zero.

An example of a portion of a conductor that is only used for conducting a current may in principle not be possible in that heat dissipates even from a solid block and a planar surface. What should be understood by a portion of a conductor primarily used for conducting current, is a varying structure or geometry for a middle segment of the conductor between the first and second terminals. When space is narrowed between components in an electrical system, if other conductors are to be passed, if the conductor has to pass through a current sensor or bushing, etc., the surface area of that particular portion of a conductor middle segment may be reduced to comply with available space, thereby typically increasing the conductor density to achieve a narrower outer dimension. In this example, at this particular portion of the conductor, the current conducting portion of the surface area of the conductor becomes high; possibly so high that a hot spot is created where additional cooling is required to continue to maintain a certain current conduction capacity. Hence, this is an example which may benefit from a combination of the conducting portion with an outgrowth portion, as described above, e.g. on each side of the narrowed part of the conductor. In this way, heat generated at the narrow space can be dissipated via the nearby outgrowths, e.g. further in combination with internal cooling channels.

An example of a portion of a conductor that is used for both heat dissipation and current conduction is a middle part between the terminals, with an airy design or geometry. In such example, the surface areas having the main purpose of dissipating heat and conducting current, respectively, may be the same or close to be the same. This is due to a geometry comprising conductor branches spaced apart from each other so that a flow of cooling air may pass freely by each conductor branch, i.e., through air gaps defined by the conductor branches. In this example the current conducting surface area is large compared to traditional conductors/busbars and windings e.g. of an electric motor. Another difference between a motor winding and a conductor of the present may be found in the circumference of the conductor. The limited space inside a motor obviously limits the circumference of the winding. This is not the case to the same extent e.g. in an electrical cabinet comprising a conductor of the present invention. More space is available and thus the circumference can be made larger leading to an airy design with airgaps for increased cooling. Further, the cross-sectional area of the individual conductor branches of a conductor according to the present invention is often lower than the cross-sectional area of a motor winding.

As mentioned, the electrical conductor 1 may comprise first and second ends 2, 3 spaced apart by a middle segment 4. One complete or final electrical conductor may comprise a plurality of interconnected electrical conductors 1 of the types illustrated/described above. In such embodiment the illustrated electrical conductors may be used as sections of the final or complete electrical conductor. Thus, a final or complete electrical conductor may comprise first and second ends 2, 3, with a plurality of first and second terminals 7, 8 at the ends or between them, e.g. with terminal holes 10 for connecting a plurality of the illustrated/described electrical conductors to form the final or complete electrical conductor.

The terminals 7, 8 may comprise one or more terminal holes 10 or other structures for connecting the electrical conductor 1 to other electrical conductors such as busbars, cables or the above-described electrical conductors, electrical components such as breakers, power modules, batteries, etc.

Alternatively, in an embodiment, one or both of the terminals 7, 8 of the electrical conductor 1 form part of an electrical component as an alternative to being provided as freely connectable locations at the conductor 1.

A terminal 7, 8 may in a simple embodiment comprise a terminal hole 10 through the terminal 7, 8. Via such hole, a bolt can go through and continue through a component with which the electrical conductor 1 is to be connected. The electrical conductor and the component are then clamped together via a nut and the bolt.

Alternatively, a terminal 7, 8 may be a click terminal that is either designed to receive a click part form a component to which the electrical conductor is the be connected or designed with a click part that is to be inserted into such other components.

Alternatively, a terminal 7, 8 at an end 2, 3 of the electrical conductor may be manufactured with a threat which when engaging with a bolt is able to assist in clamping a component to the electrical conductor 1.

Further, it should be noted, that an electrical conductor as illustrated or a complete electrical conductor comprising a plurality of electrical conductors such as the above described may have more than one first end 2 or more than one second end 3. Hence, one end of an electrical conductor 1 may branch off in e.g. three terminals each with a terminal hole. This may be advantageous in that the geometry of the electrical conductor is then designed specifically to the component to which it is to be connected. Branching off the ends into several terminals may also improve heat dissipation capacity at the possibly denser terminal portions, improve electrical connection between the conductor and components, and avoid additional connection pieces or shunts in order to connect adjacent components to a common conductor.

The middle segment 4 may comprise one, but preferably a plurality of conductor branches 5. The conductor branches 5, like the end segments 2, 3, are at least partly made of an electric conductive material such as copper or aluminium or alloys thereof, enabling the electrical conductor 1 to conduct a current between its terminals 7, 8. The design of the conductor branch(es) 5 may be optimized according to a specific purpose such as cooling, material consumption, flexibility (control in a particular direction), footprint, etc. Thus, depending on which parameter(s) the electrical conductor 1 is designed according to, the conductor branches may be designed as longitudinal cylinders (or other geometries such as oval, square, etc.), web, bionic, gyroid-like design, lattice-like design, branch-like design, or sponge-like design, coil or solenoidal designs, spirals, etc.

Thus, the electrical conductor may have a perforated surface, a non-perforated surface, a massive structure or a structure with internal channels optimizing the electrical conductor according to skin-effect and cooling, etc.

Two or more conductor branches 5 may meet in an intersection point 9 and two or more conductor branches 5 may branch off from an intersection point 9. This has the effect, that an electrical conductor is established that maintain a desired strength (determined yield point) with a minimum of material. Among others, this may reduce the cost of the electrically conductive material and reduce the weight of the conductor. It should be mentioned that two conductor branches meeting in the intersection point 9 may be the same two conductor branches leaving that intersection point 9. Alternatively, two other conductor branches may leave the intersection point, however this may be a question of definition of a conductor branch. Further one conductor branch may branch off to a plurality of conductor branches and a plurality of conductor branches may meet and form a lower number of conductor branches.

Further, it should be mentioned that the electrical conductor 1 may be designed as a plurality of electrical conductors, e.g. as a combination of three phase conductors or as a wire harness or printed circuit board traces of a printed circuit board used for mounting in an electric panel.

At least a first end 2 and a middle segment 4, but preferably also the second end 3, of the electrical conductor 1 of the present invention are monolithically formed, since they are manufacturing from a single bulk of material, which is machined to provide the electrical conductor 1. Here bulk of material should be understood as the material such as electrically conductive material of which the electrical conductor 1 is made, e.g. a solid, powder, liquid, wire, etc. Here machined should be understood as manufactured by additive manufacturing, i.e. the electrical conductor 1 is made in one piece without any mechanical connections of the first end 2, second end 3 and middle segment 4.

Note that more than one type of material, e.g. two bulks of material, may be used to manufacture the electrical conductor. One of such two or more bulks of material may be electrically non-conductive.

Note that in some embodiments it may be necessary to manufacture the electrical conductor in more than one piece. In this situation the electrical conductor may be referred to as a complete or final electrical conductor which comprises a plurality of electrical conductors 1 as described above. This may be the case e.g. if the electrical conductor needs to be mounted in a location where it cannot be inserted unless the electrical conductor is separated in two or more pieces or if the complete electrical conductor has to be larger than what is possible to manufacture by additive manufacturing. In such situation, terminals of two electrical conductors are connected, extending the length of the middle section and thereby the current path between the first end 2 and the second end 3 and thus of the complete electrical conductor. Such connection may be prepared by designing terminal holes in the conductor where, e.g., fish plates or other joints may be fastened and thereby connecting the two middle segments.

It should be noted that the electrical conductor 1 may have a non-uniform geometry/design. The design/geometry may take any machinable/printable shape. Such shape may be optimized according to conducting current (skin effect), cooling, guidance of flow of cooling fluid, other components in a panel, resistance, power loss or current displacements, etc.

In a particular embodiment, the electrical conductor 1 may have a non-uniform diameter (measured in a transversal direction) along the lengthwise direction. A well-defined diameter may nevertheless be determined e.g. at a transversal plane at which that electrical conductor 1 has its smallest diameter.

Moreover, in an embodiment of the invention the perimeter length of the electrical conductor 1 or its conductor branch(es) 5 may vary in transversal planes at different positions in the lengthwise direction of the electrical conductor 1. The perimeter length of a given part of the middle segment may simply be measured as the sum of all lengths of perimeters of branches in a given transversal plane. Hence, the perimeter length at a given part may thus be the length of the perimeter of conductor branches measured across/perpendicular to the longitudinal direction of the electrical conductor at that part. A part of a conductor may also be referred to as a portion of a conductor and should be understood as a reference to a specific portion of the conductor such as an end or middle segment.

The perimeter length of the conductor branches 5 may be the sum of lengths of perimeters of all individual conductor branches 5. As one conductor branch may split from a stem to two or more twigs, i.e. branches of a branch, the perimeter at one part of the conductor branch may be different from one part (e.g. a twig part) to another part (e.g. a stem part). Hence, the sum of lengths of perimeters of the conductor branches may be the sum of all individual twigs or of all the individual stems. In case of multiple different possible perimeter lengths for the conductor parts along the length of the electrical conductor, the smallest perimeter length may preferably be used in calculation of current conduction capability of the electrical conductor 1.

In the same way, the cross-sectional area of an electrical conductor at a given part is measured as the sum of the cross-sectional area of all conductor branches at a given part along the length of the electrical conductor. The cross-sections at that part should be measured perpendicular to the longitudinal direction of the electrical conductor.

In an embodiment, the electrical conductor 1 may comprise one or more cooling channels, where the cooling channel may be placed inside the one or more conductor branches, transversally and/or longitudinally.

The manufacturing of the electrical conductor 1 may be done by an additive manufacturing process. Such manufacturing process may be based on, but not limited to, one of the following additive manufacturing processes: 3D printing, layer by layer printing, Wire Arc Additive Manufacturing, Fused Deposition Modeling FDM, Direct Energy Deposition, Direct Metal Deposition, sintering based processes, laser based processes, for example Powder Bed Fusion PBF, such as selective laser melting SLM or selective laser sintering SLS, cold spray additive manufacturing CSAM, binder jetting or binder jet 3D printing, etc. It should be mentioned that the actual additive manufacturing process used to print or build the electrical conductor 1 may not be important as long as the material of which the electrical conductor is built is an electrically conductive material.

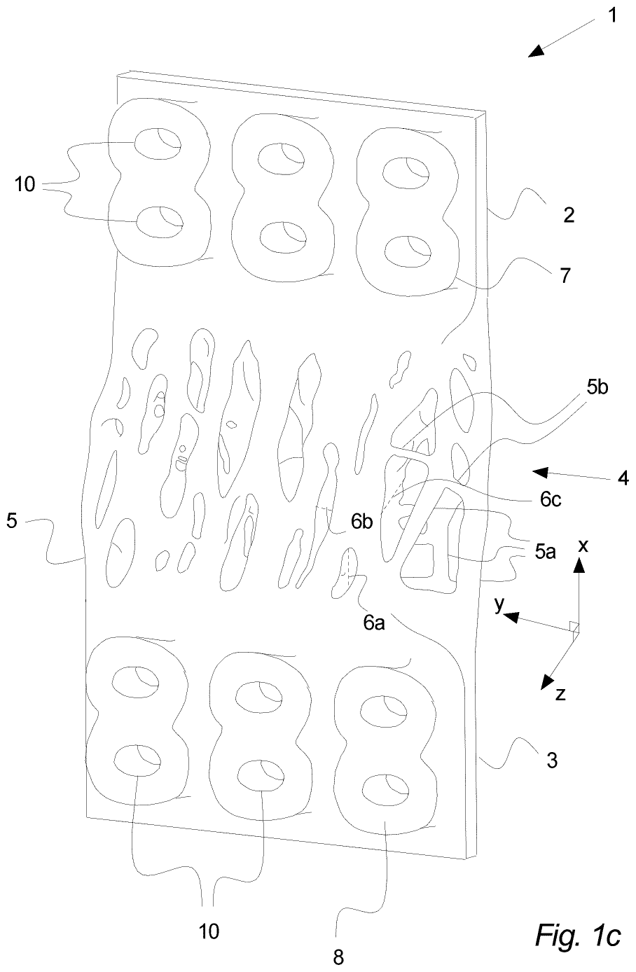

FIG. 2 illustrates method steps for machining an electrical conductor 1 according to an embodiment of the invention. The particular method relates to forming an electrical conductor with two ends or two terminals, namely a first end/terminal and a second end/terminal via a middle segment, but may be used for producing any kind of electrical conductor of the present invention.

It should be mentioned that this may include manufacturing both ends and the middle segment in one process. Hence, with additive manufacturing along the longitudinal direction of the conductor, the method may start by manufacturing, such as printing, one end, then a transition to the middle segment, possibly one or more conductor branches, then the middle segment, then a transition to the second end and finally the second end. In another embodiment, the additive manufacturing occurs transversal to the conductor's longitudinal direction, thereby for example manufacturing portions of both ends and the middle segment simultaneously, increasing the cross section with each applied layer. In another embodiment, the additive manufacturing is radial, or even arbitrary, to the conductor's longitudinal direction, for example using cold spraying CSAM or Fused Deposition Modeling FDM while rotating or freely moving either the conductor unit being built or the nozzle, or both. Preferably, the mentioned segments are manufactured in one process, e.g. as one segment is manufactured, the next segment is being manufactured. A transition part may be made between such two segments which may start or include the first segment. Similarly, the second segment may include a transition part or is connected to such transition part.

It should also be mentioned that the method could in some embodiments comprise manufacturing the middle segment and afterwards connect the end segments. The end segments could be connected while being additive manufactured or could be connected with an additive manufacturing thermal paste or glue after being made. The end segments could also be welded, glued or connected in any other way to the middle segment, e.g. by cold spraying CSAM.

An additional embodiment of the invention could be a manufacturing method that comprises two or more middle segments being additive manufactured. The two or more middle segments could be additive manufactured in the same process with the two end segments to form the electrical conductor. The two or more middle segments could also be additive manufactured separately and connected afterwards to form the electrical conductor.

The two or more middle segments could be identical or could be two differently shaped or otherwise characterized middle segments depending on where the electrical conductor should be placed in e.g., an electrical cabinet.

A transition may straightforwardly be defined as a change of size of a layer compared to a previous layer. In this way a transition may be formed as a perpendicular transition between an end segment and a conductor branch of the middle segment. Alternative, subsequent layers may change in cross-sectional area and thus form a transition as a rounded transition which may be advantageous in terms of a reduced resistance for current conducted between the ends of the electrical conductor.

A monolithic conductor according to the present invention is made from one material. One or more additional materials may be used e.g. as isolation, for heat dissipation, etc. in this case the conductor may be referred to as a polylithic conductor. No matter the number of materials, a conductor produced by additive manufacturing is produced bit-by-bit starting at a first spatial coordinate (x, y, z) and ending at a second spatial coordinate. At least when the conductor is finished the first and second spatial coordinates are electrically/mechanically connected. As mentioned several methods of manufacturing a conductor exists all including some kind of material depositing, joining or soldering to manufacture a conductor in one monolithic form.

In this document a conductor may be referred to as being manufactured layer-by-layer no matter the additive manufacturing method used. Hence, if a conductor is sliced (no matter in which orientation) and one is looking at the cross-section of the conductor it is easy to imagen that the conductor is manufactured starting with material in first point, then with material in a second point and so on. Since the conductor is volumetric i.e. has a three dimensional geometry the first point is different from the second and subsequent points at least in one of the spatial X, Y and Z directions/plans. Thus, with reference to the spatial X, Y and Z planes a conductor could be said to be built from a plurality of subsequent layers even though when manufactured all material in one plane such as X=1 and Y=0 and Z=0 is not provided as a one layer or in one layer before material in a next layer (e.g. an X=2 layer) is provided.

Hence, no matter which of the processes of manufacturing a three-dimensional object such as a conductor that is used, it can be said that the conductor is manufactured layer-by-layer even though some of these manufacturing processes are based on deposited, joined or solidified with material being added together in areas, lines, pointwise, etc. This is because no matter the additive manufacturing process the conductor is manufactured one point after the other. A plurality of points in the same plan (e.g. X=3) is considered one layer also if they are not physically connected in this plane. And when all points of this layer are added, points of the next layer (e.g. X=4) is added to the points in the X=3 layer. As mentioned, a layer may be defined in any of the planes of a spatial Cartesian coordinate system.

Alternatively, the ends may be separate segments that are connected via the middle segment. The middle segment may be printed, and during the manufacturing of the middle segment it may be attached to the ends such as printed, heated, glued or the like onto the ends. The middle segment may be joined to the ends by means of welding, printing, soldering, etc.

It should be noted that the ends may comprise terminals for connecting the electrical conductor to other electric parts/conductors/windings of an electric system. Such terminals may be manufactured like the rest of the electrical conductor by additive manufacturing i.e. monolithically formed with the ends.

In a step S1 of this particular method, considering additively manufacturing a conductor in its longitudinal direction from the first end towards the second end, the first end segment and middle segment in the form of conductor branches of a plurality of conductor branches are monolithically formed via individual transitions that may or may not include rounded connections to shape concavely rounded interior corners between the first end segment and conductor branches of the plurality of conductor branches and to spatially separate conductor branches of said plurality of conductor branches.

The step of monolithically forming the first end segment and conductor branches may be implemented using various methods, for example methods such as additive manufacturing such as 3D printing, casting, and simply removing of material, via machining, from a bulk metal slab to form conductor branches combined with a first end segment.

More specific, a known massive conductor such as a main busbar with a length of e.g. 3-5 m may conduct 1-2 A per mm2. If the same busbar was made in an airy design and e.g. with an internal cooling, then due to the improved cooling the same 1-2 A per mm2 may be conducted with the same efficiency despite the removal of material. Typical conductor materials such as aluminium and copper have temperature coefficients at approximately 0.4%/deg C. If such conductor is efficiently cooled so that the temperature is e.g. 25 deg C. lower compared to a conventional conductor, the resistance is reduced by approximately 10%. Hence approximately 10% of the material can be removed without compromising the losses. Furthermore, in AC conductors the current is not evenly distributed across the conductor volume. Typically, the current density is reduced towards the center of the conductor. Taking such considerations into account can allow for further removal of material without compromising the efficiency of the conductor.

In a step S2 of the method, the first end segment becomes electrically coupled and mechanically coupled to a second end segment via the middle segment of the electrical conductor formed by the plurality of conductor branches. This may also be monolithically achieved, e.g. by continuing the additive manufacturing, as described in step S1.

The coupling of the end segments to the middle segment could also be done by welding, gluing, male/female locking mechanism or any other way that would connect the segments both mechanically and electrically.

An optional, additional step of the method of manufacturing the conductor of the invention comprises a step prior to the step of additive manufacturing any of the first, second or middle segments. The step prior to manufacturing the electrical conductor is a step where a digital representation of the electrical conductor is designed in a software program, e.g. a 3D CAD software. The step of designing the digital representation of electrical conductor in a software program includes taking the electrical, mechanical, structural, geometry and other aspects of the physical electrical conductor into account. Thus, based on these inputs, e.g. provided by a user of the 3D CAD software, a digital representation of the conductor is provided by the 3D CAD software. When the digital representation of the electrical conductor is complete the additive manufacturing process can be started.

A further optional step may be applied i.e. a heat treatment to the finalized conductor. A heat treatment may e.g. be 4 hours at 400 C and upwards depending on the material. An advantage of heat treatment is that the particles of the manufactured conductor is mutual positioning or merging leading to higher conductivity both thermal and electrical. This is at least true for Aheadd® CP1 20/63 aluminium powders and other aluminium-iron-zirconium power solutions. Such powders may be used in laser powder bed fusion machineries. Using this type of power and heat treatment may lead to higher thermal stability, thermal conductivity, corrosion performance and surface finishing as well as higher electrical conductivity.

The middle segment may in principle have any design/geometry, for example providing flexibility thereto allowing the electrical conductor to deform. It may be formed by conductor branches being solid or having internal cavities to reduce the amount of material that is needed to manufacture the electrical conductor. It may be formed by a web or as a hybrid between conductor branches or web just to mention a few possible designs.

Internal cavities may be used as cooling channels and/or additional surface for conducting high frequency current. Accordingly, the end segments and middle segments may be designed for the particular panel/electric system in which it is used, for a particular type of current to conduct, for having a desired or dual functionality, etc.

One such functionality, beside the above-mentioned may be as a structural support. Hence, if needed the electrical conductor may be designed to assist in carrying the weight of electric components connected thereto. Hence, its dimensions may be larger than what is needed by it for carrying the required current. Similarly, its geometry may be designed for the combined purpose of mechanical support and electric conductance. This is especially true if such support is flexible/deformable in that it may both assist in supporting and at the same time assist in absorbing vibrations.

It should be mentioned that the electrical conductor 1 may be manufactured in two or more resolutions. The thicker layer the faster manufacturing. The layer thickness depends on the material and printing apparatus and may vary from a few millimetres to 20 μm, using some combinations the layer thickness is between 50 μm and 150 μm. In case of additive manufacturing resolution may be defined by thickness of the layers of which the electrical conductor is built (another word for machined and processed). A first resolution that is finer i.e. having thinner layer size than a second resolution may be used when manufacturing the interface between the electrical conductor and the part to which it is connected. Such interface may be the part of the terminal that is in contact with the other part. Alternatively, resolution may be determined by material deposition rate, material flow rate, etc. depending on the type of additive manufacturing used.

To avoid electric losses in connections between two electrical conductors it is preferred that the two parts have mating surfaces, which is most simply achieved by having planar surfaces, but may also be achieved by convex and concave combinations, mortise or finger joints, engaging teeth, cylinder and peg, tongue and groove, slide lock, etc., to further achieve additional advantages, e.g. larger surface area of connection, easier assembly of electrical conductors such as busbars in electrical systems by self-locking, etc., as long as good electrical connection is prioritized. The finer these interfaces are manufactured the better/the less post manufacturing processing is needed to ensure sufficiently mating surfaces, such as planar surfaces.

The second resolution manufactured e.g. with thicker layers would be more rough leading to more surface area. At least for middle and high frequency currents this may lead to conductance of more current without increasing the need for material/dimensions of the conductor. In fact, the middle segment may be manufactured intentionally with a corrugated surface to increase the current-carrying outer surface of the electrical conductor (current-carrying with medium and high frequencies) because of more efficient cooling due to the turbulence of, e.g., cooling air flow created due to the corrugated surface. It should be noted, that if the conductor includes an interior space, the inner surface of the conductors creating such interior space may also be corrugated for the same purpose. A corrugated surface has the effect, apart from offering a larger surface area, that it introduces turbulence in the flow of cooling fluid such as air. Increased speed of cooling fluid may lead to higher cooling effect.

As an example, the depth into the conductor which is used for conducting current at medium and high frequencies may in a specific embodiment be approximate 1.5 mm. In this specific example, the conductor is made of copper with a resistivity of approximate 1.68 μΩ cm, a relative permeability of approximate 1 at a frequency of 2 kHz. Thus, a conductor for this particular embodiment may be hollow having conductor thickness of 2 times 1.5 mm. In practice such conductor may be manufactured with a thickness of 4-5 mm leaving room for a cooling in the interior or simple reduction of conductor material and thereby weight.

Knowing that skin effect also appears at e.g. 50 Hz, a reference to a medium frequency with respect to skin effect is a reference to frequency starting around 500 Hz where the design of the conductor may account for the skin effect. The medium frequency range may be between 500 Hz and 10kHz, above 10kHz may be referred to as high frequency where skin effect is a fact (the higher frequency, the closer to the surface the current will be conducted).

Further, it should be mentioned that the outer surface may also be corrugated or designed with fins for increasing heat dissipation from the electrical conductor.

The electrical conductor resulting from the method may be used as an electrical conductor of an electrical installation. The electrical installation may be an electric panel which may be part of a renewable energy facility such as a wind turbine, solar system, grid, substation, etc. The electrical installation or system in which the electrical conductor is used may be an electric vehicle, battery system, power to x facility, ship or other minor or larger electric systems. Further, an electrical conductor resulting from the method can be used inside an electric panel, i.e. in a cabinet/enclosure, or outside such panel, it can be used to connect separated panels, etc.

A variant of an electrical conductor according to the present invention is connected to a traditional cable or busbar. In such embodiment, a traditional busbar e.g. in the back of an electric panel or a traditional cable e.g. between two electric panels may be connected to an electrical conductor of the invention. In this way a traditional cable or busbar may be connected to a component via a conductor according to the invention. Thereby, an easy connection is facilitated due to the flexibility of the electrical conductor of the invention.

However, note that manufacturing the electrical conductor, and thus accomplishing the electrical and mechanical coupling between the first end segment and the second end segment, is typically performed prior to installing the electrical conductor in the electrical installation, and prior to installing the electrical installation in the renewable energy facility. Thus, according to typical embodiments of the invention, the electrical and mechanical coupling is performed prior to installation/integration of the electrical conductor. Nevertheless, methods according to the invention are not necessarily restricted to a particular sequence of steps. Further, various methods according to the invention may comprise additional steps, such as performing digital geometry optimization, additively manufacturing the electrical conductor, and conducting current.

Summing up, a designer is designing a digital representation of the conductor according to electrical, mechanical, structural, etc. requirements in e.g. a 3D CAD software such as Solidworks. Files (digital representation) from such 3D developing tool is exported to e.g. a 3D printer, where the conductor is printed according to the CAD files.

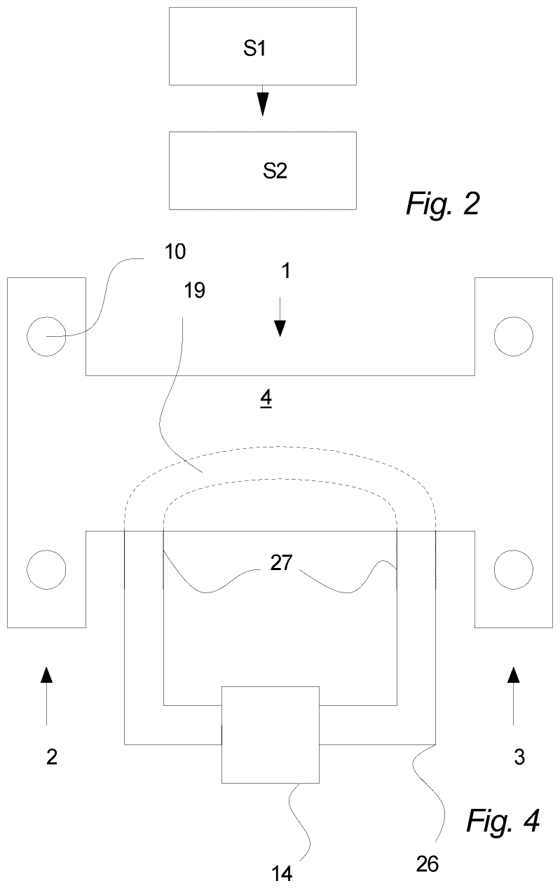

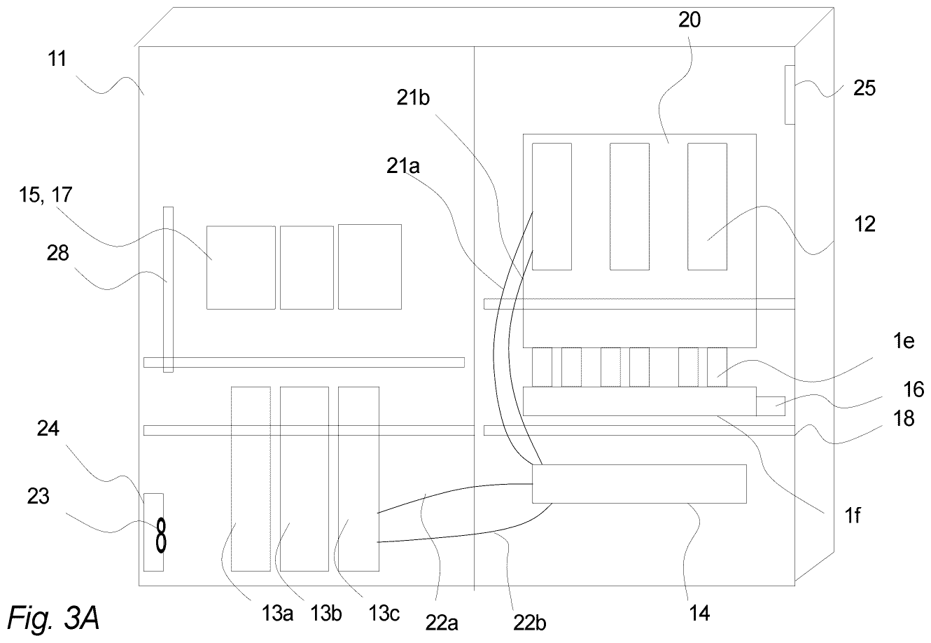

FIG. 3a illustrates a projection of a high-power converter 11 according to an embodiment of the invention. This converter 11 comprises a circuit breaker 17 of which the back side is illustrated. This circuit breaker 17 is at the same time referred to power inlet 15 of the converter 11 i.e. via the circuit breaker 17 it is possible to disconnect the converter 11 from its supply. The power supply to the converter 11 may be the grid or a local power generator such as a wind turbine or a solar panel.

The circuit breakers 17 are in this embodiment connected to a reactor 13 with cables. In this embodiment, the reactor 13 is, via cables, connected to one of four conductor 1a-1d which may be referred to as transition busbars. The transition busbar Id is completing the connecting of the reactor to the power modules 12. This is illustrated in detail at FIG. 3b.

The output side of the power modules 12 are in this embodiment connected to a laminated busbar plate 20 which via conductor le is connected to a main output conductor 1f. This main output conductor is in one end referred to as power outlet 16 and cables to a load is connected here.

The main busbar may be a massive busbar as known in the art whereas the transition busbars 1a-1f may have a non-massive geometry e.g., manufactured by additive manufacturing.

A transition busbar of the present invention may be manufactured at least partly by an additive manufacturing process and thus the geometry may be tailor made to the footprint, available space, cooling capacity, current capacity, etc. that is limiting or required from the transition busbar. A few examples of geometry and design of a transition busbars are illustrated above in FIGS. 1a-1c.

It should be mentioned that studs may be provided on the surface of conductors 1 comprised by the cabinet 31 of the present invention. Studs are advantageous in that if located e.g. every 5 mm then they will create a turbulence at the surface which increases the cooling efficiency of the conductor. The studs may be attached during manufacturing such as during additive manufacturing or post manufacturing e.g. via cold spray.

The power modules 12 comprise a plurality of semiconductor switches such as IGBTs. These power modules 12 are control by a converter controller so as to perform the function of e.g. an inverter or rectifier. On that node, the illustrated converter 11 is an AC to DC converter where three phases e.g., from the utility grid enter the converter 11 and is converted to a DC supply e.g., for an electrolyser. It should be noted that the converter 11 may also be a DC to AC or DC to DC converter.

The illustrated converter 11 is a three phased AC to DC converter which on the AC side is connected to the utility grid and on the DC side connected to an electrolyser. Typically, when the converter 11 is converting from or to AC, the converter could be referred to as a three phased converter. However, it should be mentioned that it could be a DCDC converter and as such a one phased converter.

The reactor 13 in the illustrated embodiment comprises three inductors 13a-13c magnetically connected via their respective cores. The purpose of these inductors is to reduce the di/dt i.e., ensure that the current is not increasing uncontrollable.

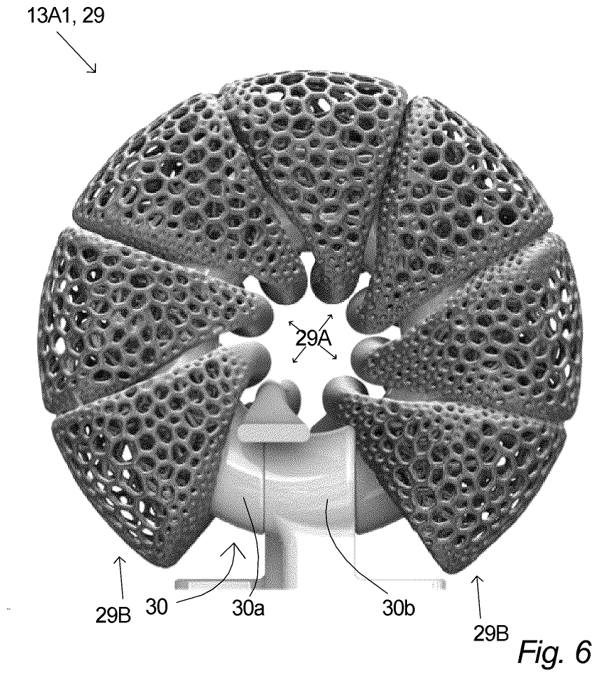

In an embodiment, the illustrated inductors 13a-13c may be replaced by one or more inductors 13a-1 having non-uniform electrical windings such as the one illustrated in FIG. 6. Depending on the required inductance of the reactor, more than one of the illustrated inductors 13a-1 may be implemented in a parallel or series connection. It should be mentioned that a reactor and an inductor may sometimes refer to the same component. One feature that sometimes is used to differentiate an inductor from a reactor is that reactors are used in AC circuits, where inductors are used in both AC and DC circuits.

FIG. 6 illustrates as mentioned an inductor 13a-1 i.e., a coil 29 is coiled around a core 30 of a ferromagnetic material. The ferromagnetic core 30 in this embodiment of the invention is a closed core. The inner part 29a of the electrical windings are inside the ferromagnetic core 30 and the outer part 29b of the electrical windings are placed on the outside of the core 30.

The core 30 may as illustrated in FIG. 6 comprise a first core part 30a and a second core part 30b, where the first core part 30a is a loop and the second part 30b connects the two ends of the loop from the first core part 30a to make the core 30 a closed core. The design of the loop for the first core part may be configured so that the coil 29 can be guided onto the 30. This could be done after both the coil 29 and the first core part 30a has been manufactured at least partly by additive manufacturing such as 3D printed, or the coil 29 could be printed around the first core part 30a. The coil 29 with the first core part 30a is open and the core could be closed by connecting the second core part 30b to both ends of the first core part 30a. It may also be possible to print the coil 29 around a core 30 directly.

In other embodiments of the invention the first and second core part could have a core design e.g., as a square-frame, oval or circularly shaped core. The core design could also comprise an additional core part not illustrated, which for a square-framed core could be an additional core part in the middle, which divides the square-frame into two square-frames such as the reactor 13 of FIG. 3.

With respect to the magnetic field a closed core is optimal and with respect to windings a straight solenoid design is optimal. As these do not match, a compromise must be made to provide the optimal reactor/transformer. The compromise may include two vertical core parts each with a solenoid winding where the core in at least one end but preferably in both ends are connected. Thereby, the core turns or branches off by an angular part relatively to the vertical part. The solenoid winding along the vertical core parts may be uniform, however at the angular core part (if that has an angle of 90° or less) is preferred to have a non-uniform winding as the windings exemplified in FIG. 6. This is because as soon as the core bend or branch off and the coil has to follow, there is more space available at the outer part than at the inner part of the coil.

Accordingly, the core may be a square, comprising two straight parts connected with a spheric part, circular, etc. note that any of these shapes may be monolithically.

The core 30 of a ferromagnetic material could be made iron such as an iron powder which make it possible to mould/shape the core as if the core manufactured by additive manufacturing. The ferromagnetic core 30 could comprise a cooling channel built into the core, with a cooling channel inlet and a cooling channel outlet. The cooling channel inlet and the cooling channel outlet could be placed in each end of the core. The cooling channel could run through the entire core from the cooling channel inlet to the cooling channel outlet. An interior cooling channel may extend as one conduit or branch off (and maybe meet again) in two or more conduits.

The cooling channel may guide a cooling fluid for cooling the core 30. The cooling fluid could be a liquid cooling fluid such as Glycol, water solutions, dielectric fluids, etc. The cooling fluid may be circulated in a cooling system with some kind of heat exchanger.

Transformers and reactors are magnetic components which can be based on magnetic cores or core-less (air-inductors). A single winding only exhibits self-inductance, and may be referred to as an inductor. When two or more windings are magnetically coupled (through a magnetic core or through air), the multiple windings are magnetically connected through mutual inductances, and can be referred to as a transformer or coupled inductor. For multiple winding inductors/transformers, the windings exhibit both mutual inductance and self-inductance. A special form of coupled inductor is the three-phased reactor, which functionally is equivalent to three individual self-inductances, although the three windings are magnetically coupled. Such structure is often referred to as simply a reactor, although such structure involves mutual inductances, which is present in a transformer. Winding for such magnetic components may advantageously be of the type described above.

Using a coil 29 as described above to provide components such as a reactor or transformer is advantageous in that the size of such components is reduce e.g. up to ⅓ or ½ of the size of such component build from traditional technology. This significantly reduced cost of material and foot print which is especially advantageous e.g. in large power generating plants such as wind turbines.

Two or more coils 29 may be connected in parallel or in series. This may be relevant if requirements to voltage or current requires a certain number of winding. Thus, it may be easier to manufacture e.g. three reactors each with 5 windings and connect these in series than to manufacture one with 15 just to mention one example. It may also turn out, that three series connected winding may be easier to cool than one reactor with three times the number of windings.

Accordingly, the electric conductor or windings described in this document may comprise one first conductor branch that may branch off to a plurality of second conductor branches, each of these second conductor branches may further branch off to a plurality of third conductor branches and so on through the middle segment of the electric conductor/winding. In this way, following the direction of the current flow through the electric conductor/winding from a first end to a second end, current is allowed to flow in the first conductor branch, then allowed to divide into a flow in the second conductor branches and again allowed to divide into a flow in the third conductor branches and so on into additional nth conductor branches.

In an embodiment, if current is flowing from a first end segment to a second end segment, the first conductor branch may have a first cross-sectional area, the second conductor branches may have a second cross-sectional area which is smaller than the first cross-section area. Following, the third conductor branches may have a cross-sectional area smaller than the second cross-sectional area. Accordingly, the cross-sectional area of the conductor branches may be varied in size in the longitudinal direction of the middle segment.

As described above, the conductor branches of the electric conductor/winding may branch off into a plurality of additional (nth) conductors. In the same way, the conductor branches may also converge from a higher number of conductor branches into a lower number of conductor branches.

It should be mentioned that a cross-sectional area of the middle segment at one distance from a first end segment may be the same as a cross-sectional area of the middle segment at a second distance from the first end segment while the number of conductor branches at the first distance is different from the number of conductor branches at the second distance.

Further, it should be mentioned that the cross-sectional area of the middle segment at the first and second distances from a first end segment may be different while the number of conductor branches may be the same. Of course, the cross-sectional area and the number of conductor branches may also be the same at the first and second distances from the first end segment.

The branching off may be in one plane. This plane may be of a tangent to the surface of an electrical conductor having a curved design. Further note that such branching off may either be at the within the fixed uniformity of the conductor and/or it may be from one conductor to another e.g. via a joint/fixing of two conductors.

It should be mentioned that embodiment of the electrical conductor/winding may also include designs where the conductor branches branch off from the first end segment to a plurality of conductor branches and converge again into the second end segment without branching off between the first and second end segments.

Further note that the through-hole through a conductor having an airy design defining the terminals holes and/or fastening holes may have a solid wall. The solid wall may be of the same or different material as the rest of the conductor and be used to provide strength to the terminal/fastener hole when these are used e.g. to bolt two conductors together or fasten the conductor. The cross-sectional area of the solid wall is determined by the force which e.g. a bolt is applying to the conductor to sufficiently securing the conductor. As an example, the cross-sectional area of the solid walls may be between 0.2 mm and 20 mm such as between 0.3 mm and 15 mm, such as between 0.4 mm and 10 mm such as between 0.5 mm and 0.8 mm.

If the solid wall of a fastening hole is made of the same conducting material as the conductor, the diameter of the fastening hole may be large enough to allow an insulating bushing between the conductor material and the bolt. Such insulating bushing may comprise a collar resting on the surface of the conductor and thereby insulating the bolt head from the conductor material. Such bushing with collar may be manufactured by additive manufacturing. Alternatively, the solid part of the fastening hole can be made of an electrically insulating material. electrically insulating material in form of a filament, e.g. made of thermoplastics such as polylactic acid PLA or acrylonitrile butadiene styrene ABS filament.

Further note that the conductor of the present invention illustrated may be manufactured by additive manufacturing may be manufacture as a curved conductor. i.e. no post processing is needed to bend the conductor. The curve is typically 90 degrees or less, but could in principle be any angle. Such curved conductor may reduce number of connections in a panel and thereby mounting time and also losses in connections conductors.

Further, the conductor of the present invention being manufactured by additive manufacturing may be twisted between 1 degree and 359 degrees. In this way the end segments may be oriented differently and fastened e, g, to other conductors with bolts that are having non-parallel center axis. This is leading to a more flexible design of the layout in a panel and sometimes also easier mounting of the conductors in a panel.

The converter 11 may comprise a filter 28 such filter may e.g. comprise capacitors, damping resistors, and trap chokes. This filter 28 is included in the converter to ensure that the output voltage from the converter is smoothed e.g. to comply with grid codes.

As illustrated, the converter 11 may comprise a cooling system 14. The cooling system 14 may include cooling loops 21, 22, 26 via which the components such as the reactor, filter and power modules are cooled. The cooling system may circulate a cooling fluid, such as a liquid or gaseous coolant. Such liquid coolant may e.g. be selected as a type of oil which may be non-electrical conductive and thereby work as both cooling fluid and isolator, water, deionized water, Glycol, liquid, metal such as Gallium, mercury, etc. The cooling system may circulate the cooling fluid in the cooling loop with a flow speed in the range of 4 L/min to 10 L/min per power module. Therefore, the cooling system should be able to provide a flow of cooling fluid in the range of 48 L/min to 120 L/min in electrical systems having parallel power modules on each of three phases (12 power modules x 4-10L7min). The temperature of the cooling fluid is preferably below 55 C in that it is desired to maintain a temperature below 55 C in the high-power electric system.

In addition to traditional converter cooling systems, the converter 1 of the present invention is alone or furthermore cooled via the transition busbars. These busbars comprise internal channels that may be part of one or more of the cooling loop 21, 22, 26. In this way the cooling fluid may be directed closer to the component, and more important it may cool components that with known technology is not possible to include in a cooling loop.

This is possible in that e.g. the transition busbar carrying a high current to a power module thereby is generating a temperature increase can be cooled from a fluid conducted in the internal channel 19 which is included in a cooling loop. More specifically, a first part of a cooling loop 21a, 22a or 26a may conduct cooling fluid to the component or through the component and the heated cooling fluid may return to the cooling system 14 via a second part of the cooling loops 21b, 22b and 26b

The cabinet comprising the converter 11 may in addition to the cooling from closed internal channels 19 described above also be cooled be an air flow from a fan 23. Such air flow may be provided between an air inlet 24 and an air outlet 25 depending on the fan 25. This flow of air may also transport heat from inside of the cabinet or more particular from the surface of the conductors such as the transition busbars and out of the cabinet.

This traditional way of cooling a cabinet has a rather limited effect on cooling the components such as the conductors of the cabinet. However, in the present invention where e.g. transition busbars are manufactured in an airy design, such air flow has an improved cooling effect. This is because a transition busbar or a conductor branch thereof may along most of its length, in some embodiments along all of its length, be cooled from all angles i.e. a 360° cooling of the conductor branches is possible.

It should be noted that the above-mentioned cooling should be understood as one kind of temperature regulation i.e. a reduction of temperature. A closed internal channel as described above may also be used for regulating the temperature up. This is especially relevant to avoid e.g. moisture/condensed water on busbars.

Accordingly, an internal channel may be used to circulate a fluid with which it is possible to regulate temperature of the busbar comprising the internal channel. In this way it is possible to either increase or decrease the temperature of the busbar and thereby of the cabinet in which the busbar is enclosed. This is advantageous in that it has the effect, that drips of water e.g. condensation on the busbar can be vaporized prior to conducting current through the busbar. In this way the risk of arc flash occurring is reduced.

Alternatively, or in addition internal channels 19 may lead to an increase in current possible to conductor to the power modules per cross-sectional area of the conductor. Hence, the amount of material needed to conduct a given current is reduced. In fact, it may be possible to conduct higher currents by a transition busbar with internal channel and/or airy design/geometry than possible to conduct with known massive conductor.

More specific, a known massive conductor such as a main busbar with a length of e.g. 3-5 m may conduct 1-2 A per mm2. If the same busbar was made in an airy design and e.g. with an internal cooling, then due to the improved cooling the same 1-2 A per mm2 may be conducted with the same efficiency despite the removal of material. Typical conductor materials such as aluminium and copper have temperature coefficients at approximately 0.4%/deg C. If such conductor is efficiently cooled so that the temperature is e.g. 25 deg C. lower compared to a conventional conductor, the resistance is reduced by approximately 10%. Hence approximately 10% of the material can be removed without compromising the losses. Furthermore, in AC conductors the current is not evenly distributed across the conductor volume. Typically, the current density is reduced towards the center of the conductor. Taking such considerations into account can allow for further removal of material without compromising the efficiency of the conductor.

Further, a conductor such as a transition busbar having internal cooling channel and an airy design having a length of e.g. 1-2 m may conduct 10-15 A per mm2 and in an extreme case with massive cooling an a distance no longer than e.g. 10 cm, such conductor may conduct 50 A per mm2. Care should be taken when reducing the cross-sectional area in that more heat is generated which need to be removed if the same current should be conducted by a smaller cross-sectional area. The loss increases quadratic with the increase of current. Therefore, the efficiency of the conductor is also reduced when the material hereof is reduced.

In addition to the above-mentioned features, the converter 11 of the present invention may include one or more of several additional features which makes it advantageous over prior art converters.

One such feature is a non-uniform electrical conductor 1. With a non-uniform electrical conductor 1 it is possible to make a more compact design of the converter 11 in that the electrical conductor (including main and transition busbars) may be shaped according to available space and location of components in the cabinet. This may include branching off in two or more conductor branches, change to an airy design if additional cooling for some reason is required, narrow the cross-sectional area of the conductor 1 and thereby establish a heater if required for some reason of if the conductor 1 has to go through a current sensor, etc. As an example of the advantage of being able to create heat could be mentioned that during start up, if a certain part of a cabinet is prone to condensation, that part of the cabinet may be heated up by conducting current through a narrow cross-sectional area of the conductor in such area. Another example is a circuit breaker which may require a certain heat dissipation from a connected conductor. Such requirement to heat dissipation may be complied with, with less material by a conductor with varying/airy geometry compared to known massive conductors. In fact, it may be possible to rate up the circuit breaker due to the optimized heat dissipation from the conductor connected to the circuit breaker.

Another such feature is electrical conductors such as those denoted 1a-1d of FIG. 3b. These conductors may, by additive manufacturing, be monolithically formed as one conductor including all the benefits from the individual conductors. Hence, one multifunctional conductor may be manufactured having varied cross-sectional area according to where cables are connected (1a), conducting of current (1b), cooling (1a, 1c), facilitates mount of several such as five ferrite cores (1c) and flexibility (1d). By manufacturing one multifunctional conductor with two or more of these characteristics' material may be saved, better cooling may be obtained, more flexible conductor may be provided leading to easier mounting, the number of connections of conductors is reduced and a more compact layout of the converter 1 may be achieved Such multifunctional conductor may have a wedge formed part for connecting cables, a twisted design allowing the conductor to form a solenoid of five windings around a core and a branch off for connecting to the power modules.

Further, mounting such multifunctional conductor is faster than connecting four individual conductors and less manual mounting eliminate sources of errors and when connecting two parts requires space for tool and larger distances to other components in general due to concerns of tolerances. Further, by using conductors with airy design and/or internal cooling channels the design can be more compact because of the optimized cooling and thus conductors 1 may be located closer to other components.

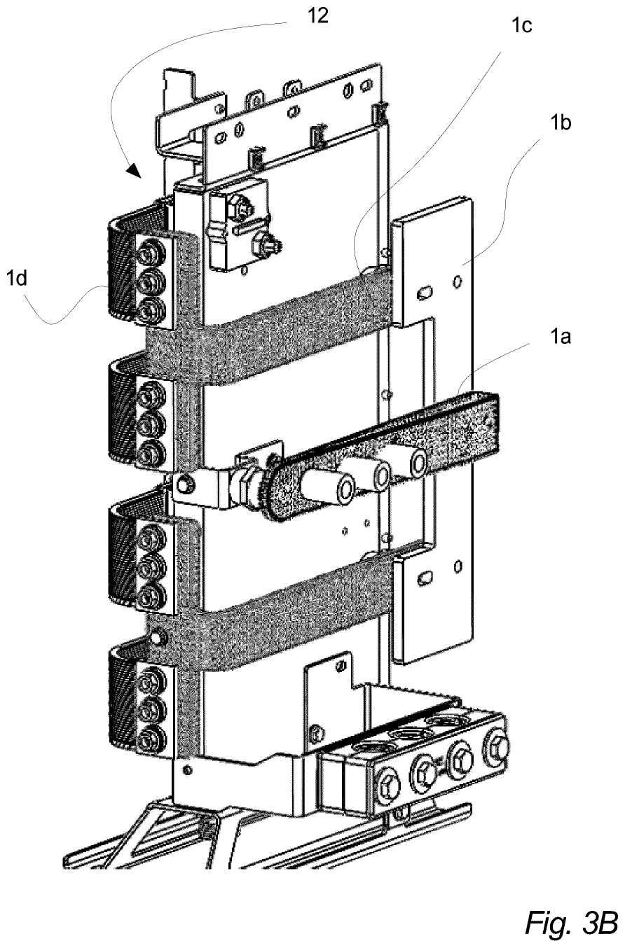

FIG. 4 illustrates a busbar 1 with an internal channel 19 connected to a third cooling loop 29 and thus to a cooling system 14. The cooling system may also be referred to as a temperature regulation system and may comprise a heat exchanger which may by a conventional heat exchanger working based on well known principles. Thus, the cooling fluid circulated in the loop 26 may be heated as it passes through the internal channel 19 and subsequently exchange heat in the heat exchanger e.g. with another fluid of another loop or with a fluid such as air. Alternatively, the regulation system 14 may comprise a heat pump. Such heat pump may also work according to well-known principles such as pumping a liquid into the channel 19 where it evaporates and returns as a gas to the pump/compressor. Here the pressure of the fluid is increased and heat as consequence hereof is exchanged with surroundings before it is introduced into the channel 19 again.

It should be mentioned that the cooling loop may include more than one channel 19. Thus, channels 19 of two conductors 1 may be connected with a pipe or hose of a non-conductive material. The outlet of one conductor may be fluidly connected to the inlet of another conductor and in this way establish an extended loop which includes a plurality of channel 19 of one or more conductors 1. If the hose is of a non-conductive material in principle, the busbars may not need to be of the same phase. In this case it may be preferred to have a fluid circulated in the hoses which is non-conductive.

Thus, a cooling loop may comprise a first manifold supplying two or more channels 19 with a flow of cooling fluid and a second manifold collecting fluid from the two or more channels 19 to guide it to a heat exchanging part of the cooling system 18.

The channel 19 may e.g. be formed as or with a channel extension 27. Hence, as the conductor 1 is manufactured, the inlet and/or outlet of the channel 19 may also be manufactured. In this way the fluid connections to the channel 19 by the loop 26 is easy to establish simply by a providing a loop pipe over the extension and e.g. in addition provide a hose clamp around the pipe. Such extension 27 may be designed in any desired relevant way and thus be relatively long for it to end at a desired location. Such desired location may be desired e.g. with respect to service and maintenance, mounting, etc.

The surface of the busbar 1 may be airy or flat and it may comprise non-illustrated air guides for guide a flow of air in a predetermined direction. Further, the busbar 1 may include a heat sink for transporting heat from the surface of the busbar to the surroundings. Both the air guide and the heat sink may be integrated i.e. manufactured as an outgrowth from the surface of the busbar. Hence, during manufacturing of the busbar, the air guide and/or the heat sink may be monolithic formed as one with the busbar. Alternatively, the heat sink and/or the air guide may be external mounted to the busbar. Such mounting may be via incorporated mounting points of the busbar. Such mounting points may be monolithic formed as one with the busbar during manufacturing of the busbar.

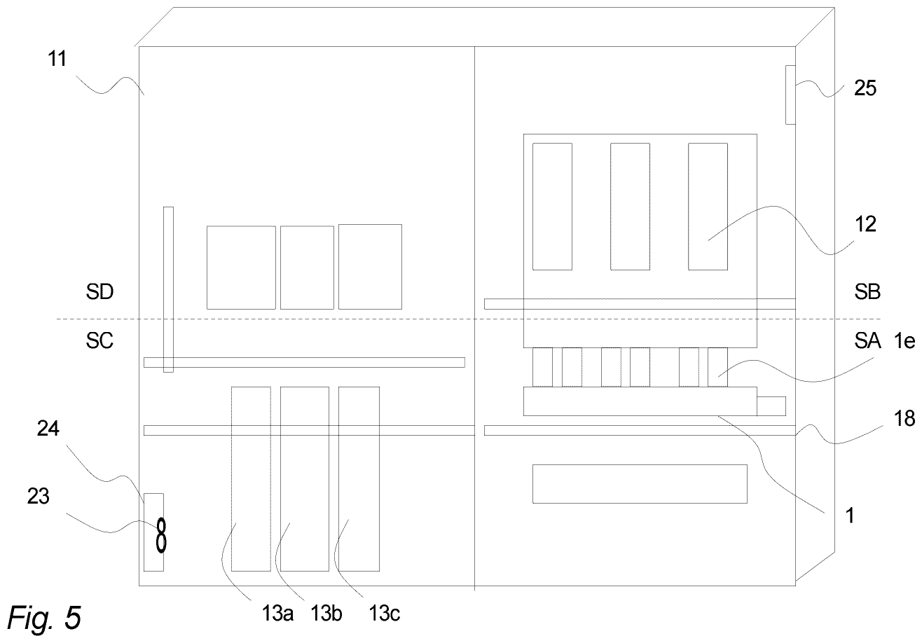

FIG. 5 illustrates a converter assembly according to the present invention. The converter assembly comprises an electric cabinet 31 divided in several sections each with a specific functionality. Hence a first section is a power conduction section SA with the purpose of conducting current from the power modules 12 to the power output 16. Another section is a power conversion section SB where a desired output voltage and current is shaped by power modules 12. Yet another section is a filter section SC where a reactor 13 is performing a current rise limitation (a di/dt limitation). Yet another section is an auxiliary section SD where current to the converter 11 may be interrupted, output voltage and current waveform may be smoothened by a filter, excessive power may be burned off in one or more dump loads, etc.

The converter assembly further comprises a cooling system 4 that is designed for local cooling. Hence, targeted cooling of one or more of the above-mentioned sections is performed. Targeted cooling should be understood dedicated local cooling by an independent cooling loop. As an example a first cooling loop 21 may be dedicated to cooling of the power modules of the power conversion section, a second cooling loop 22 may be dedicated to cooling of the reactor of the filter section and so on. Additional cooling loops may be dedicated for cooling components of the auxiliary section and of the power conducting section.

To obtain a better control or lower temperature without increasing cooling capacity, these local cooling loops of the converter assembly is supported by spot cooling of selected electrical conductor 1. In this context, spot cooling should be understood as cooling inside the conductor i.e. “behind” the surface of the conductor so to speak. This is possible because the selected electrical conductors comprise an internal cooling channel and/or an airy geometry/design. Hence, by the cooling channel it is possible to conduct a liquid or gaseous coolant and by the airy geometry/design it is possible to provide a flow of air through the conductor geometry. In this way the cooling of the conductor 1 is significantly improved compared to cooling of traditional conductors.

The internal channels and airy design/geometry is possible to manufacture because the conductors 1 are manufactured by an additive manufacturing process.

From the above it is now clear that the invention relates to a high-power convert and a high-power converter assembly in which some components are electrically connected with conductors 1 also referred to as transition busbars. These transition busbars are advantageous to use in that since they are produced by additive manufacturing, they may take any printable form. Hence, in terms of cooling the can be optimized to have a particular airy design and have internal cooling channels. Based on this more current can be conducted with less copper/aluminium used in the conductors.

Also the transition busbars are advantageous in that they may be multifunctional i.e. they are designed to have more than one function/advantage such as conduct current, be part of a cooling system, replace several transition busbars with one, etc.

The invention has been exemplified above with the purpose of illustration rather than limitation with reference to specific embodiments. Details of specific embodiment have been provided in order to understand the aim of the invention. Please note, that detailed descriptions of well-known systems, devices, circuits, and methods have been omitted so as to not obscure the description of the invention with unnecessary details.

### LIST

1. Electrical conductor
2. First end
3. Second end
4. Middle segment
5. Conductor branch
   a. Longitudinal conductor branch
   b. Transversal conductor branch
6. Air gap
   a. Longitudinal airgap (in X direction)
   b. Transversal airgap (in Y direction)
   c. Vertical airgap (in Z direction)
7. First terminal
8. Second terminal
9. Intersection point
10. Terminal hole
11. High-power converter
12. Power modules
13. Reactor
14. Cooling system
15. Power inlet
16. Power outlet
17. Circuit breaker
18. Support structure
19. Internal channel
20. Laminated busbar plate
21. First cooling loop
22. Second cooling loop
23. Fan
24. Air inlet
25. Air outlet
26. Third cooling loop
27. Channel extension
28. Filter
29. Coil
   a. Inner part
   b. Outer part
30. Core
   a. First core part
   b. Second core part
31. Electric cabinet
SA. Power conduction section
SB. Power conversion section
SC. Filtering section
SD. Auxiliary section

1. A three-phased high-power converter comprised by an electrical cabinet, said high-power converter comprising:
at least three power modules;
at least one reactor;
a cooling system configured for cooling said at least three power modules and said at least one reactor; and
a plurality of high-power electrical conductors establishing a three-phased current path from a power inlet of said electrical cabinet via said at least three power modules, and via said at least one reactor to a power outlet of said electrical cabinet,
wherein at least one of said high-power electrical conductors is a transition busbar manufactured at least partly by an additive manufacturing process to obtain a geometry that is multifunctional with a non-massive core,
wherein said non-massive core is provided as an open channel inside said transition busbar with airgaps in an outer perimeter of the transition busbar configured for allowing an air flow through the interior of said transition busbar, and
wherein said transition busbar is multifunctional in that, in additional to conduct current, said airflow passing through the interior of the transition busbar, is configured to temperature regulate said transition busbar.

2.-6. (canceled)

7. The three-phased high-power converter according to claim 1, wherein said cooling system comprises a heat exchanger and a first cooling loop configured to circulate a liquid cooling fluid from said heat exchanger via a first part of said first cooling loop to a power module mounting plate and via a second part of said first cooling loop back to said heat exchanger.

8. The three-phased high-power converter according to claim 1, wherein said cooling system further comprises a second cooling loop configured to circulate a liquid cooling fluid from said heat exchanger via a first part of said second cooling loop to an internal cooling channel of at least one of said at least one reactor and via a second part of said second cooling loop back to said heat exchanger.

9.-11. (canceled)

12. The three-phased high-power converter according to claim 1, wherein said at least one reactor comprising an electrical winding comprising an inner part and an outer part, wherein a diameter of said inner part is smaller than the diameter of said outer part.

13. (canceled)

14. The three-phased high-power converter according to claim 1, wherein at least one current path branches off through said electrical winding.

15. The three-phased high-power converter according to claim 1, wherein said high-power electrical conductor is manufactured at least partly with a concave geometry in the surface of a middle segment (4) or one of a first end and a second end of said high-power electrical conductor.

16. The three-phased high-power converter according to claim 1, wherein at least one of said first end and said second end are monolithically formed with said middle segment.

17. The three-phased high-power converter according to claim 1, wherein at least one of said plurality of high-power electrical conductors are manufactured in an airy geometry.

18. The three-phased high-power converter according to claim 1, wherein said high-power electrical conductor has a resonance vibration frequency of at least 5 Hz, for example at least 20 Hz, for example at least 30 Hz, for example at least 70 Hz, for example at least 150 Hz for example at least 300 Hz, for example at least 500 Hz.

19. The three-phased high-power converter according to claim 1, wherein at least a middle segment of at least one of said plurality of high-power electrical conductors comprises at least one internal channel.

20. The three-phased high-power converter according to claim 19, wherein said at least one internal channel is included in a third cooling loop (26) and configured to guide a cooling fluid circulated in said third cooling loop (26) through the interior of said at least one of said plurality of high-power electrical conductor.

21. (canceled)

22. The three-phased high-power converter according to claim 19, wherein said at least one internal channel is configured to comprise a cooling pipe.

23. The three-phased high-power converter according to claim 19, wherein said at least one internal channel comprises a plurality of flow guides.

24. (canceled)

25. The three-phased high-power converter according to claim 1, wherein at least one of said plurality of high-power electrical conductors comprises at least one air guide.

26.-27. (canceled)

28. The three-phased high-power converter according to claim 1, wherein of at least one of said plurality of high-power electrical conductors comprises at least one integrated heat sink.

29.-31. (canceled)

32. A high-power converter assembly comprised by an electrical cabinet, said power converter assembly comprising:
a power conduction section comprising high-power electrical conductors,
a power conversion section comprising a plurality of power modules,
a filtering section comprising a plurality at least one reactor,
an auxiliary section, comprising auxiliary components and
a cooling system,
wherein components of said power conversion section, said filtering section and said auxiliary section is connected via high-power electrical conductors,
wherein said cooling system is configure for local cooling of at least said power conversion section and said filtering section,
wherein at least one of said high-power electrical conductors is a transition busbar at least partly manufactured by an additive manufacturing process to obtain a geometry that is multifunctional with a non-massive core,
wherein said non-massive core is provided as an open channel inside said transition busbar with airgaps in an outer perimeter of the transition busbar configured for allowing an air flow through the interior of said transition busbar, and
wherein said transition busbar is multifunctional in that, in additional to conduct current, said airflow passing through the interior of the transition busbar, is configured to temperature regulate said transition busbar.

33. The high-power converter assembly according to claim 32, wherein said high-power converter assembly is an AC to DC, DC to AC, DC to DC or AC to AC converter.

34. The high-power converter assembly according to claim 32, wherein at least one of said high-power electrical conductors are manufactured with an internal channel.

35.-36. (canceled)

37. The high-power converter assembly according to any of claim 32, wherein said at least one of said high-power electrical conductors comprise airgaps between two or more conductor branches.

38. The three-phased high-power converter according to claim 1, wherein the transition busbar has a varied cross-sectional area in that the cross-sectional area at a first and second distances from a first end segment is different.
